(19) United States
(12) Patent Application Publication
(10) Pub. No.: US 2026/0186018 A1
(43) Pub. Date: Jul. 2, 2026

(54) TESTING APPARATUS AND METHODS OF USING THE SAME

(71) Applicant: Taiwan Semiconductor Manufacturing Company, Ltd., Hsinchu (TW)

(72) Inventors: Cheng-Lin Tsai, Changhua County (TW); Yuan-Li Lin, Taichung City (TW); I-Te Lee, Kaohsiung City (TW); Yu-Ming Hsiao, Hsinchu County (TW)

(73) Assignee: Taiwan Semiconductor Manufacturing Company, Ltd., Hsinchu (TW)

(21) Appl. No.: 19/002,773

(22) Filed: Dec. 27, 2024

(51) Int. Cl. G01R 1/04; G01R 1/067; G01R 31/28

(52) U.S. Cl. CPC G01R 1/0441; G01R 1/06716; G01R 31/2886

(57) ABSTRACT

A testing apparatus for a semiconductor structure includes a socket including a flange portion, a central portion, a first conductive connector, and a second conductive connector. The central portion is surrounded by the flange portion, where the central portion includes a first opening and a second opening respectively penetrating the central portion, and a size of the first opening is less than a size of the second opening. The first conductive connector penetrates through the central portion through the first opening. The second conductive connector penetrates through the central portion through the second opening. The first conductive connector and the second conductive connector are configured to transmit electric signals for testing the semiconductor structure.

### BACKGROUND

Modern day integrated chips comprise millions or billions of semiconductor devices formed on a semiconductor substrate (e.g., silicon substrate). In addition, developments of packaging technology in shrinking sizes of semiconductor devices and electronic components make the integration of more devices and components into a given volume possible and lead to high integration density of various semiconductor devices and/or electronic components. The semiconductor devices on the semiconductor substrate and/or semiconductor devices of the package are tested for functional defects and/or performance characteristics. A testing is done by an electrical test in which a prober sends electrical test signals to the semiconductor devices. The electrical test signals check the functionality of the semiconductor devices and identify devices that fail to meet design specifications.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flowchart of a method for using a testing apparatus in accordance with some embodiments of the disclosure.

FIG. 2 is a schematic explosive view illustrating a testing apparatus in accordance with some embodiments of the disclosure.

FIG. 3 is a schematic cross-sectional view of the testing apparatus depicted in FIG. 2.

FIG. 4A through FIG. 4G are schematic, enlarged plane views respectively showing various embodiments of a configuration of testing pins in a portion of a central portion of a socket included in the testing apparatus depicted in FIG. 2.

FIG. 5A through FIG. 5B are schematic, enlarged plane views respectively showing various embodiments of a configuration of a pair of power and ground pins in the testing apparatus depicted in FIG. 2.

FIG. 6 is a schematic cross-sectional view of an assembly of a testing apparatus and a semiconductor structure in accordance with some embodiments of the disclosure.

FIG. 7 is a schematic explosive view illustrating a testing apparatus in accordance with some embodiments of the disclosure.

FIG. 8 is a schematic cross-sectional view of the testing apparatus depicted in FIG. 7.

FIG. 9A through FIG. 9G are schematic, enlarged plane views respectively showing various embodiments of a configuration of testing pins in a portion of a central portion of a socket included in the testing apparatus depicted in FIG. 7.

FIG. 10A through FIG. 10B are schematic, enlarged plane views respectively showing various embodiments of a configuration of a pair of power and ground pins in the testing apparatus depicted in FIG. 7.

FIG. 11 is a schematic cross-sectional view of an assembly of a testing apparatus and a semiconductor structure in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a testing apparatus including a socket with two different sizes of openings, where the small openings are adopted for placement of testing pins (or probe) transmitting electrical signals, and the large openings are adopted for placement of pairs of testing pins (or probe), each pair including a testing pin (or probe) for transmitting a power signal and a testing pin (or probe) for transmitting a ground signal (e.g., a ground). These signals may be referred to as electric signals. In accordance with some embodiments of the disclosure, the testing pins (or probe) can be pogo pins for testing a semiconductor structure of a chip-level (e.g., as a final product after packaging). In accordance with some embodiments of the disclosure, the testing pins (or probe) can be MEMS pins for testing a semiconductor structure of a wafer-level. One pair of testing pins (or probe) may be referred to as a paired power/ground pin (or probe) or a power/ground pin (or probe) paring structure.

In accordance with some embodiments of the disclosure, each pair of testing pins (or probe) includes a power pin (or probe), a ground pin (or probe) and a dielectric structure of high dielectric constant (high-k) interposing between the power pin (or probe) and the ground pin (or probe), where the dielectric structure is formed with a predetermined shape to increase a contact area between the power pin (or probe) and the ground pin (or probe) and decrease a distance between the power pin (or probe) and the ground pin (or probe). With such configuration of the pairs of testing pins in the testing apparatus, a capacitive reactance between the power pin (or probe) and the ground pin (or probe) is increased so to obtain better power distribution network (PDN), and a shorting between the power pin (or probe) and the ground pin (or probe) is prevented. Therefore, a power integrity (PI) performance in the testing apparatus of the disclosure is improved, thereby reducing/minimizing the risk of device damage. In accordance with some embodiments of the disclosure, each pair of testing pins (or probe) includes a power pin (or probe), a ground pin (or probe) and a plurality of capacitors interposing between the power pin (or probe) and the ground pin (or probe), where the capacitors are mounted to and between the power pin (or probe) and the ground pin (or probe) so to separating the power pin (or probe) and the ground pin (or probe), on the other hand. With such configuration of the pairs of testing pins in the testing apparatus, a capacitive reactance between the power pin (or probe) and the ground pin (or probe) is increased so to obtain better PDN. Therefore, a PI performance in the testing apparatus of the disclosure is improved, thereby reducing/minimizing the risk of device damage.

It is understood that additional processes may be provided before, during, and after the illustrated method, and that some other processes may only be briefly described herein. In the disclosure, it should be appreciated that the illustration of components throughout all figures is schematic and is not in scale. The method may be part of a wafer level packaging process. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

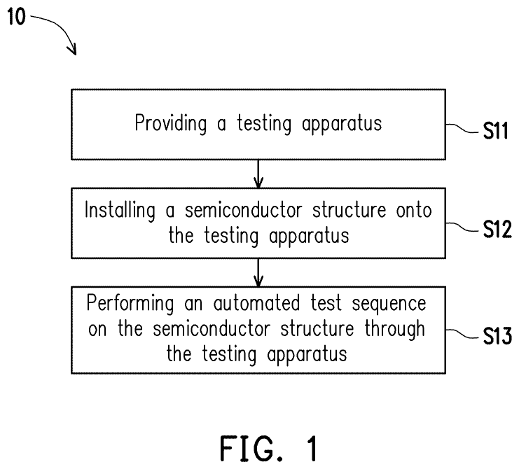

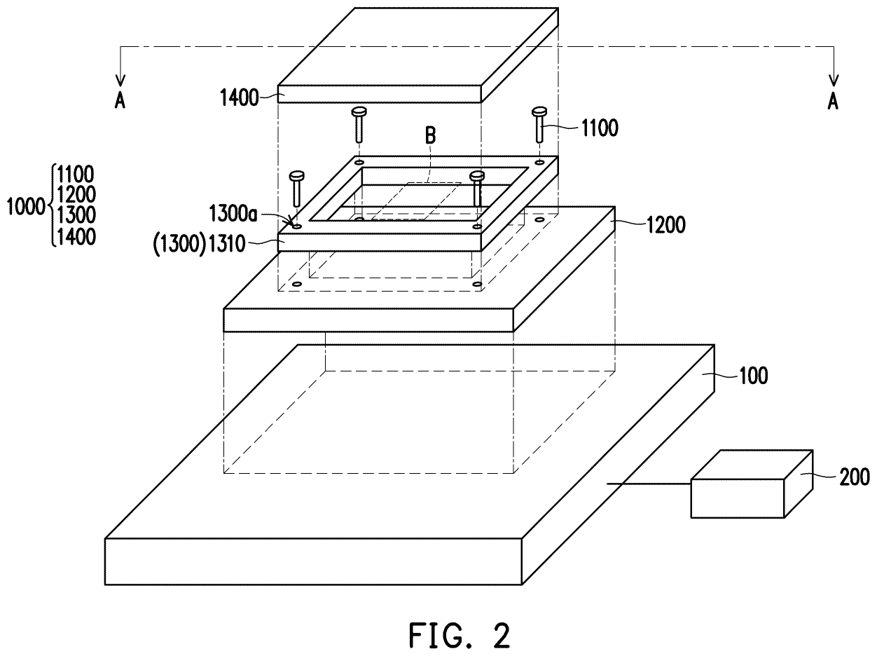

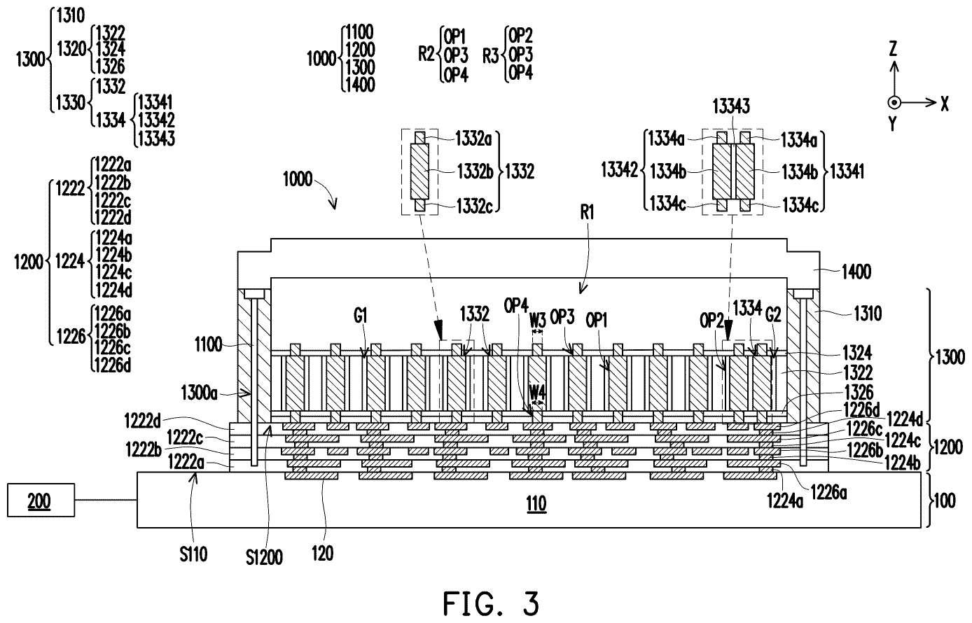

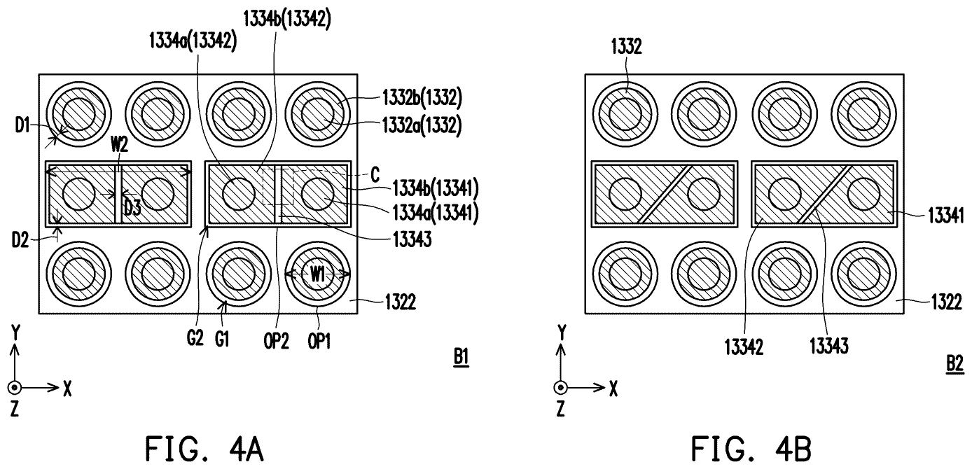

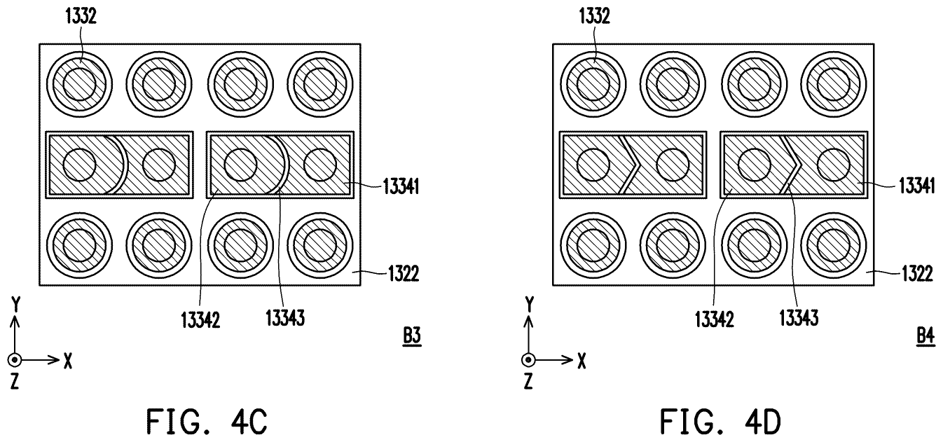

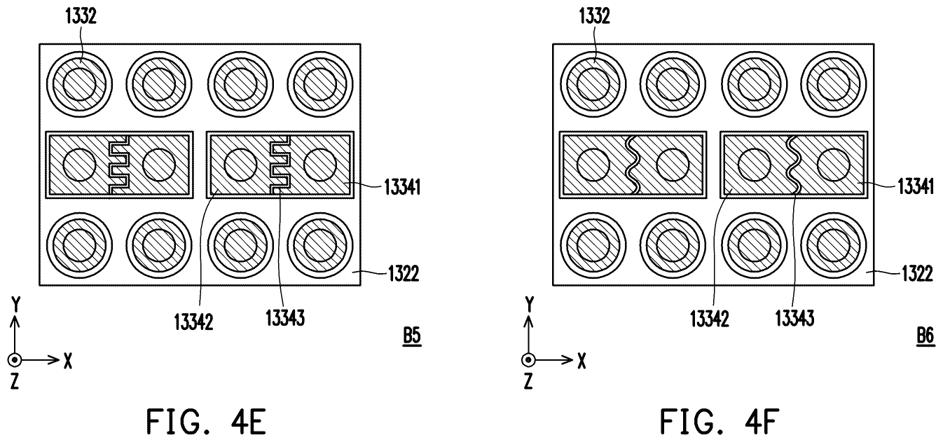

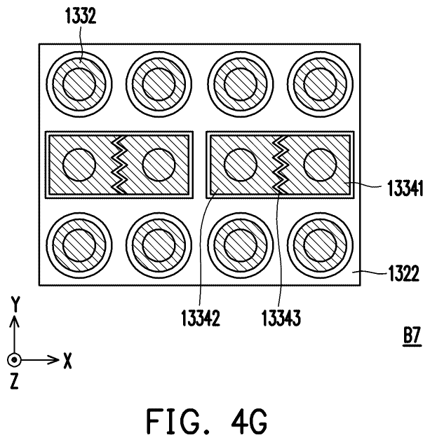

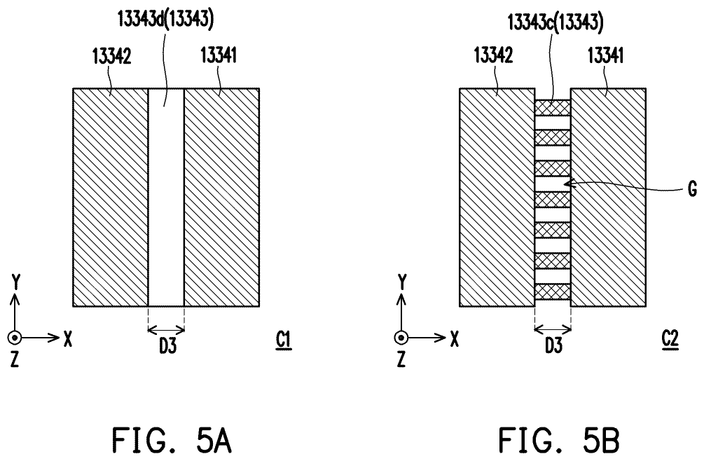

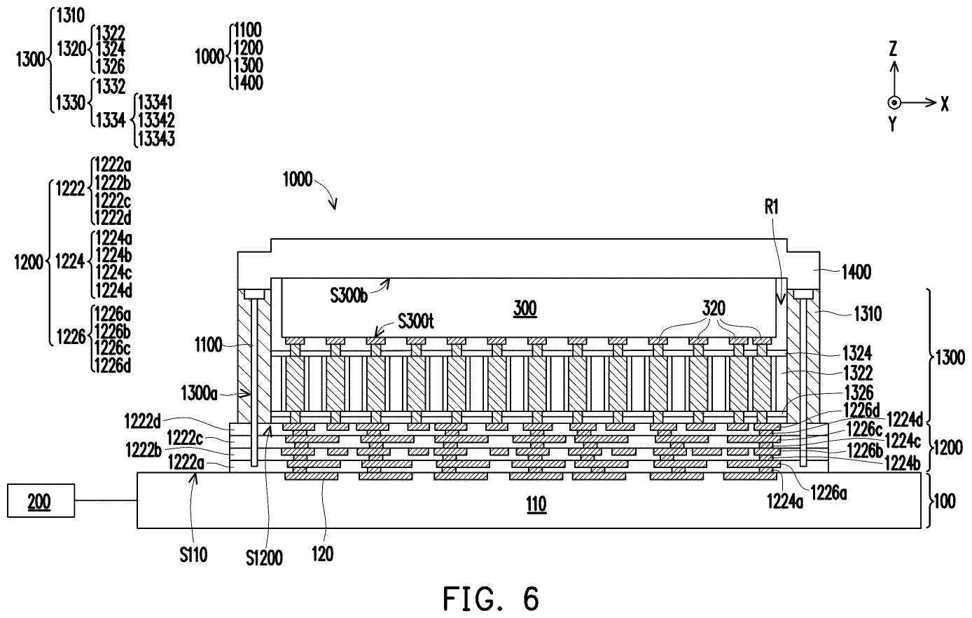

FIG. 1 illustrates a flowchart of a method for using a testing apparatus in accordance with some embodiments of the disclosure. FIG. 2 is a schematic explosive view illustrating a testing apparatus (e.g., 1000) in accordance with some embodiments of the disclosure. FIG. 3 is a schematic cross-sectional view of the testing apparatus (e.g., 1000) depicted in FIG. 2, where FIG. 3 is a cross-sectional view taken along a line A-A depicted in FIG. 2. FIG. 4A through FIG. 4G are schematic, enlarged plane views respectively showing various embodiments of a configuration of testing pins (e.g., 1330) in a central portion (e.g., 1320) of a portion of a socket (e.g., 1300) included in the testing apparatus (e.g., 1000) depicted in FIG. 2, which are outlined by a dashed-box B depicted in FIG. 2 (e.g., a dashed-box B1 in FIG. 4A, a dashed-box B2 in FIG. 4B, a dashed-box B3 in FIG. 4C, a dashed-box B4 in FIG. 4D, a dashed-box B5 in FIG. 4E, a dashed-box B6 in FIG. 4F and/or a dashed-box B7 in FIG. 4G). FIG. 5A through FIG. 5B are schematic, enlarged plane views respectively showing various embodiments of a configuration of a pair of power and ground pins (e.g., 13341, 13342) in the testing apparatus (e.g., 1000) depicted in FIG. 2, which are outlined by a dashed-box C depicted in FIG. 4A (e.g., a dashed-box C1 in FIG. 5A and/or a dashed-box C2 in FIG. 5B). FIG. 6 is a schematic cross-sectional view of an assembly of a testing apparatus (e.g., 1000) and a semiconductor structure (e.g., 300) in accordance with some embodiments of the disclosure. The embodiments are intended to provide further explanations, but are not used to limit the scope of the disclosure.

In some embodiments, a testing apparatus is provided, in accordance with step S11 of the method 10 depicted in FIG. 1. Referring to FIG. 2 and FIG. 3, in some embodiments, a testing apparatus 1000 is placed onto and electrically coupled to a testing circuit structure 100, where the testing circuit structure 100 is further electrically coupled to a controller 200. In other words, the testing apparatus 1000 is electrically coupled to the controller 200 through the testing circuit structure 100. For example, the testing apparatus 1000 includes a holding element 1100, a circuit board structure 1200, a socket 1300 and a cover 1400. In some embodiments, the socket 1300 is disposed on and electrically connected to the circuit board structure 1200, the holding element 1100 penetrates through the socket 1300 and further extended into the circuit board structure 1200 so to lock the socket 1300 onto the circuit board structure 1200, and the cover 1400 is laid on (e.g., directly placed onto) the socket 1300. As shown in FIG. 3, for example, the circuit board structure 1200 of the testing apparatus 1000 is disposed on and electrically coupled to the testing circuit structure 100. A space R1 may be confined by the socket 1300 and the cover 1400 for accommodating an object to-be-tested or a device under test, such as a semiconductor structure 300 (described later in FIG. 6).

In some embodiments, the testing circuit structure 100 includes a substrate 110, an internal circuitry (not shown) embedded in the substrate 110 and including metallization layers and vias (not shown) interconnected, and a plurality of conductive contacts 120 exposed from the substrate 110 (e.g., a surface S110 thereof) for external connection (e.g. to the circuit board structure 1200) and electrically connected to the internal circuitry. The substrate 110 may be made of a material with a sufficient stiffness (which may be quantified by its Yong's modulus) to protecting the internal circuitry embedded therein and the conductive contacts 120 exposed therefrom. In some embodiments, the substrate 110 includes a substrate made of a dielectric material; for example, a polymer such as polyimide (PI), polybenzoxazole (PBO), benzocyclobutene (BCB), a nitride such as silicon nitride, an oxide such as silicon oxide, a silicon oxynitride, phosphosilicate glass (PSG), borosilicate glass (BSG), boron-doped phosphosilicate glass (BPSG), a combination thereof or the like. In some embodiments, the conductive contacts 120 are distributed on the surface S110 of the substrate 110, and are exposed for electrically connecting with the later-formed elements/features (e.g. the circuit board structure 1200). In some embodiments, the internal circuitry (including the metallization layers and the vias) is embedded in the substrate 110 and provides a routing function for the substrate 110, where the metallization layers and the vias included in the internal circuitry are electrically connected to the conductive contacts 120. For example, one of the conductive contacts 120 is electrically coupled to another contact pad 120 through the internal circuitry.

The materials of the conductive contacts 120 may include conductive materials formed by electroplating or deposition, such as aluminum, titanium, copper, nickel, tungsten, and/or alloys thereof, which may be patterned using a photolithography and etching processes. In some embodiments, the conductive contacts 120 include copper pads, copper alloy pads, aluminum pads or aluminum alloy pads. The number of the conductive contacts 120 included in the testing circuit structure 100 is not be limited to the drawings of the disclosure, which may be selected and designated based on the demand and the design requirement/layout. The materials of the metallization layers and the vias included in the internal circuitry may include conductive materials formed by electroplating or deposition, such as aluminum, titanium, copper, nickel, tungsten, and/or alloys thereof, which may be patterned using a photolithography and etching processes. In some embodiments, the metallization layers included in the internal circuitry are patterned copper layers, and the vias included in the internal circuitry are copper vias. In one embodiment, one metallization layer and a respective one via may be formed together by dual damascene process. In an alternative embodiment, one metallization layer and a respective one via may be formed by single damascene process, separately. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The materials of the metallization layers and the vias may be the same, the disclosure is not limited thereto. Alternatively, the material of the metallization layers may be different from the material of vias. In certain embodiments, the testing circuit structure 100 includes an organic flexible substrate or a printed circuit board that having a circuit structure therein and connecting to the controller 200.

The controller 200 may be with or without built-in memory devices (e.g., for storing testing settings or test results). For example, the controller 200 includes analog and digital circuits, a processor, or a combination thereof. The controller 200 may be implemented by circuitry including, but not limited to, analog circuit, digital circuit, semiconductor integrated circuit such as at least one processor (e.g., a central processing unit (CPU)), at least one application specific integrated circuit (ASIC), and/or at least one field programmable gate array (FPGA), or a combination thereof. The at least one processor may be configured or programmed, by reading one or more instructions from at least one machine readable tangible medium, to perform the functions of the controller 200 as described further below. For example, the controller 200 may include testing sequence for testing the object to-be-tested or the device under test (e.g., the semiconductor structure 300 of FIG. 6). The controller 200 may be an automatic (or automated) testing equipment (ATE) to perform measurements (by generating and sending testing electric signals and receiving responsive electric signals) and evaluate the test results (e.g., analysis of the responsive electric signals) for testing the integrated circuits and internal circuitries of the object to-be-tested or the device under test (e.g., the semiconductor structure 300 of FIG. 6). In certain embodiments, the controller 200 is an external component being electrically coupled to the testing circuit structure 100, as shown in FIG. 2 and FIG. 3. However, the disclosure is not limited thereto; alternatively, the controller 200 may be a built-in component of the testing circuit structure 100.

It is appreciated that, the object to-be-tested has electrical characteristics (e.g., voltage or current characteristics) that are desired to be measured and/or tested at various positions, where the testing apparatus 1000 is provided to connect with the controller 200 via the testing circuit board 100 to facilitate efficient identification of failures in interconnects inside the object to-be-tested. For example, the testing circuit structure 100 serves as a loadboard for an ATE, where a variety of electrical components/devices (such as integrated circuits, resistors, capacitors, inductors, relays, etc.) are employed to make up the loadboard's test circuit. However, the disclosure is not limited thereto, in alternative embodiments, the testing circuit structure 100 serves as a loadboard for an ATE, which is free of additional electrical components/devices. The disclosure is not limited thereto. The testing circuit structure 100 sometimes may be referred to as a main testing board.

In alternative embodiments, the substrate 110 includes a core layer (not shown) with a plurality of plated through holes penetrating therethrough, where dielectric structures are respectively located on two opposite sides thereof, and each of the dielectric structure includes one internal circuitry (including the metallization layers and vias) embedded therein. For example, the internal circuitries formed in the dielectric structures are electrically coupled to each other through the plated through holes penetrating the core layer, where the conductive contacts 120 are formed atop a respective one of the internal circuitries, and some of the conductive contacts 120 are electrically coupled to each other through the internal circuitries and the plated through holes therebetween. In other words, the plated through holes may provide electrical paths between the electrical circuits located on two opposing sides of the core layer. With such, the conductive contacts 120, the internal circuitries and the plated through holes penetrating the core layer together provides a routing function for the substrate 110. In certain embodiments, one internal circuitry and the respective one dielectric structure are together referred to as a build-up layer located over the core layer. In a non-limiting example, if only one build-up layer is presented, the conductive contacts 120 may be electrically coupled to the build-up layer through the plated through holes penetrating the core layer, where the core layer is disposed between the conductive contacts 120 and the build-up layer. In another non-limiting example, if only one build-up layer is presented, the conductive contacts 120 may be electrically coupled to the plated through holes penetrating the core layer through the build-up layer, where the build-up layer is disposed between the conductive contacts 120 and the core layer. In further another non-limiting example, if there are two build-up layers being disposed two opposite sides of the core layer and electrically coupled to each other through the plated through holes penetrating the core layer, the conductive contacts 120 may be electrically coupled to the plated through holes penetrating the core layer through a respective one build-up layer, where the respective one build-up layer is disposed between the conductive contacts 120 and the core layer. In yet further another non-limiting example, if there are two build-up layers being disposed two opposite sides of the core layer and electrically coupled to each other through the plated through holes penetrating the core layer and additional conductive contacts are presented, the conductive contacts 120 may be electrically coupled to the plated through holes penetrating the core layer through a respective one build-up layer, and the additional conductive contacts may be electrically coupled to the plated through holes penetrating the core layer through the other build-up layer, where the respective one build-up layer is disposed between the conductive contacts 120 and the core layer, and the other build-up layer is disposed between the additional conductive contacts and the core layer.

In some embodiments, the core layer includes a core dielectric layer, such as prepreg (which contains epoxy, resin, silica filler and/or glass fiber), Ajinomoto Buildup Film (ABF), resin coated copper foil (RCC), polyimide, photo image dielectric (PID), ceramic core, glass core, molding compound, a combination thereof, or the like. However, the disclosure is not limited thereto, and other dielectric materials may also be used. The core dielectric layer may be formed by a lamination process, a coating process, or the like. In some embodiments, the plated through holes may be lined with a conductive material and filled up with an insulating material. In some embodiments, the method of forming the plated through holes includes the following operations. First, through holes are formed at the predetermined positions in the core layer by, for example, a mechanical or laser drilling, an etching, or another suitable removal technique. A desmear treatment may be performed to remove residues remaining in the through holes formed in the core layer. Subsequently, the through holes formed in the core layer may be plated with one or more conductive materials to a predetermined thickness, thereby providing the plated through holes penetrating the core layer. For example, the through holes formed in the core layer may be plated with copper with an electroplating or an electroless plating.

The formation of the build-up layer may include sequentially forming a plurality of dielectric layers and a plurality of conductive patterns, where the dielectric layers and the conductive patterns are alternately stacked over the one surface of the core layer. For example, a material of the dielectric layers is ABF, prepreg, RCC, polyimide, PID, molding compound, a combination thereof, or the like. The core layer and the dielectric layers may be made of the same material. For example, the material of the core dielectric layer and the dielectric layers may be molding compound such as epoxy molding compound (EMC). The dielectric layers may be formed by a lamination process, a coating process, or the like. The number of layers of conductive patterns and the number of layers of dielectric layers are not limited in the disclosure, and thus may be selected and designated based on the demand and design requirements/layout. The disclosure is not limited thereto.

In some embodiments, the circuit board structure 1200 is disposed on (e.g., in physical contact with) and electrically coupled to the testing circuit structure 100, as shown in FIG. 3. In some embodiments, the circuit board structure 1200 includes a plurality of build-up layers (not labeled) each including a metal trace 1226 (e.g. 1226a, 1226b, 1226c, or 1226d), a metal via 1224 (e.g. 1224a, 1224b, 1224c, or 1224d) connected to the metal trace 1226, and a dielectric layer 1222 (e.g. 1222a, 1222b, 1222c, or 1222d) surrounding the metal trace 1226 and the metal via 1224. The metal trace 1226a, the metal via 1224a and the dielectric layer 1222a together constitute a first build-up layer; the metal trace 1226b, the metal via 1224b and the dielectric layer 1222b together constitute a second build-up layer; the metal trace 1226c, the metal via 1224c and the dielectric layer 1222c together constitute a third build-up layer; and, the metal trace 1226d, the metal via 1224d and the dielectric layer 1222d together constitute a fourth build-up layer. For example, the metal via 1224a connects the metal trace 1226a overlying thereto and the conductive contacts 120 respectively underlying thereto, and the metal traces 1226a and the respective conductive contacts 120 are electrically connected to each other through the metal via 1224a. The metal via 1224b connects the metal trace 1226b overlying thereto and the metal trace 1226a underlying thereto, and the metal traces 1226a and 1226b are electrically connected to each other through the metal via 1224b. The metal via 1224c connects the metal trace 1226c overlying thereto and the metal trace 1226b underlying thereto, and the metal traces 1226b and 1226c are electrically connected to each other through the metal via 1224c. The metal via 1224d connects the metal trace 1226d overlying thereto and the metal trace 1226c underlying thereto, and the metal traces 1226c and 1226d are electrically connected to each other through the metal via 1224d. That is, the electrical connection paths between the metal traces 1226d and the metal vias 1224a are established. Owing to such configuration, the metal traces 1226 and the metal vias 1224 together constitute a routing structure, thereby the circuit board structure 1200 is capable of providing a routing function. Only four build-up layers are shown in the disclosure for illustrative proposes only, and the disclosure is not limited thereto. The number of the build-up layers included in the circuit board structure 1200 may be selected and designated based on the demand and design requirement/layout.

The material of the dielectric layers 1222 may include polyimide, epoxy resin, acrylic resin, phenol resin, BCB, PBO, or any other suitable polymer-based dielectric material, and may be formed by deposition, lamination or spin-coating. The material of the metal vias 1224 and the metal traces 1226 may include aluminum, titanium, copper, nickel, tungsten, and/or alloys thereof, and may be formed by electroplating or deposition. The disclosure is not limited thereto. The dielectric structures dielectric layers 1222, the metal vias 1224 and the metal traces 1226 independently may also be patterned by a photolithography and etching process. In one embodiment, one metal via 1224 and a respective one metal traces 1226 overlying thereto may be formed together by dual damascene process. In an alternative embodiment, one metal via 1224 and a respective one metal traces 1226 overlying thereto may be formed by single damascene process, separately. As shown in FIG. 3, the circuit board structure 1200 is electrically connected to the testing circuit structure 100 through the metal vias 1224 (e.g., 1224a). However, the disclosure is not limited thereto; alternatively, additional (conductive or electrical) connectors (not shown) may be presented between the metal vias 1224a of the circuit board structure 1200 and the conductive contacts 120 of the testing circuit structure 100 to obtain proper electrical connections therebetween.

In other words, the electric signals generated from the controller 200 may be rerouted to the sockets 1300 through the testing circuit board 100 and the circuit board structure 1200 for testing the object to-be-tested, and/or the responsive electric feedbacked from the object to-be-tested being received by the socket 1300 may be rerouted to the controller 200 through testing circuit board 100 and the circuit board structure 1200 for further processing. In certain embodiments, the circuit board structure 1200 sometimes may be referred to as a loadboard for the socket 1300, where a variety of electrical components/devices (such as integrated circuits, resistors, capacitors, inductors, relays, etc.) are employed to make up the loadboard's test circuit. However, the disclosure is not limited thereto, in alternative embodiments, the circuit board structure 1200 serves as a loadboard for the socket 1300, which is free of additional electrical components/devices.

In addition, the circuit board structure 1200 may be properly secured onto the testing circuit structure 100 by a holding element (not shown), where the holding element may be a fastener (e.g., blots or blots threaded with nuts, with or without washer), a clamp, an adhesive e.g., made of dielectric material, a metallic material, or a combination thereof), or the like, the disclosure is not limited thereto, as long as the placement of the circuit board structure 1200 over the testing circuit structure 100 is properly secured. For example, as shown in FIG. 3, the circuit board structure 1200 directly stands on the surface S110 of the testing circuit structure 100.

In some embodiments, the socket 1300 is disposed on and electrically coupled to the circuit board structure 1200. Back to FIG. 2 through FIG. 3, in some embodiments, the socket 1300 is in physical contact with the circuit board structure 1200 (e.g. a surface S1200 of the circuit board structure 1200). For example, the socket 1300 includes a flange portion 1310, a central portion 1320, and a plurality of conductive connectors 1330 penetrating through the central portion 1320. In some embodiments, the flange portion 1310 is disposed on (e.g., in physical contact with) and electrically isolated from the circuit board structure 1200, and the central portion 1320 is disposed over (e.g., spatially spacing apart from) and electrically isolated from the circuit board structure 1200. As shown in FIG. 3, the flange portion 1310 may be directly stand on the surface S1200 of the circuit board structure 1200, where the flange portion 1310 may be in physical contact with the dielectric layer 1222d of the circuit board structure 1200 and distant from the metal trace 1226d. In some embodiments, the conductive connectors 1330 are disposed on and electrically connected to the metal trace 226d of the circuit board structure 1200.

In some embodiments, the flange portion 1310 is connected to the central portion 1320, where the flange portion 1310 is at a periphery of the central portion 1320. In some embodiment, the central portion 1320 includes a first portion 1322, a second portion 1324 and a third portion 1326, where the second portion 1324 and the third portion 1326 are respectively disposed at two opposite sides of the first portion 1322. In other words, the flange portion 1310 laterally surrounds the central portion 1320, where the flange portion 1310 are connected to sidewalls of the first portion 1322, the second portion 1324 and the third portion 1326 of the central portion 1320. In a top view (e.g., a X-Y plane) along a direction Z (e.g., a stacking direction of the socket 1300 and the circuit board structure 1200 of the testing apparatus 1000), the central portion 1320 may be in a rectangular shape, for example. However, the disclosure is not limited thereto; alternatively, in the top view along the direction Z, the central portion 1320 may be in a square-shape, a circle-shape, an ellipse-shape, or any suitable polygonal shape. In some embodiments, in the top view along the direction Z, the first portion 1322, the second portion 1324 and the third portion 1326 of the central portion 1320 have the same shape and dimension. The flange portion 1310 is in an annular form, such as a (continuously) ring shape in the top view, for example. In some embodiments, in the top view along the direction Z, the shape of the flange portion 1310 corresponds to the shape of the central portion 1320.

In some embodiments, the flange portion 1310 is made of a material with a sufficient stiffness (which may be quantified by its Yong's modulus) for protecting and supporting elements (e.g., the conductive connectors 1330 and/or the central portion 1310) disposed thereon/therein. The material of the flange portion 1310 may include a conductive material, a dielectric material or a combination of dielectric material and conductive material. For example, the conductive material includes a metallic material (such as a metal or a metal alloy). The material of the flange portion 1310 may include stainless steel, polyester, polyimide, glass, epoxy, or the like. In some embodiments, the material of the central portion 1320 include a dielectric material capable of providing a specific stiffness that ensuring the physical and mechanical strength of the sockets 1300. The stiffness (which may be quantified by its Yong's modulus) can be in the range of about 10 GPa to about 30 GPa. In some embodiments, the central portion 1320 is made of plastic material or the like. For example, In some embodiments, the materials of the first portion 1322, the second portion 1324 and the third portion 1326 of the central portion 1320 are the same, such as plastic material. The disclosure is not limited thereto. Alternatively, the materials of the first portion 1322, the second portion 1324 and the third portion 1326 of the central portion 1320 may be different, in part or all. For one non-limiting example, the materials of the first portion 1322 and the second portion 1324 are the same, but different from the material of the third portion 1326. Alternatively, the materials of the first portion 1322 and the third portion 1326 may be the same, but different from the material of the second portion 1324. Or alternatively, the materials of the second portion 1324 and the third portion 1326 may be the same, but different from the material of the first portion 1322. Alternatively, the materials of the first portion 1322, the second portion 1324 and the third portion 1326 of the central portion 1320 may all be different from each other. The disclosure is not limited thereto. The flange portion 1310 is electrically isolated from the central portion 1320, for example.

The first portion 1322 may be referred to as a base or a body of the central portion 1320, the second portion 1324 may be referred to as a top lid (structure) or a top cap (structure) of the central portion 1320, and the third portion 1326 may be referred to as a bottom lid (structure) or a bottom cap (structure) of the central portion 1320. In some embodiments, the first, second and third portions (1322, 1324, 1326) of the central portion 1320 are used to hold the conductive connectors 1330 in proper position inside the socket 1300. In addition, the second portion 1324 and the third portion 1326 may be properly secured onto the first portion 1322 by a holding element (not shown), where the holding element may be a fastener (e.g., blots or blots threaded with nuts, with or without washer), a clamp, an adhesive e.g., made of dielectric material, a metallic material, or a combination thereof), or the like. The disclosure is not limited thereto, as long as the placements of the second portion 1324 and the third portion 1326 over the first portion 1322 are properly secured.

Continued on FIG. 3, the first portion 1322 of the central portion 1320 has a plurality of openings OP1 and a plurality of openings OP2 penetrating therethrough, where the openings OP1 and the openings OP2 are laterally arranged next to each (e.g., along directions X and/or Y) and distant apart from one another. In some embodiments, in the top view (e.g., the X-Y plane), the openings OP1 has a lateral size (or saying a maximum size) W1 being less than a lateral size (or saying a maximum size) W2 of the openings OP2, as shown in FIG. 4A. In some embodiments, the second portion 1324 of the central portion 1320 has a plurality of openings OP3 penetrating therethrough, where the openings OP3 are laterally arranged next to each (e.g., along the directions X and/or Y) and distant apart from one another. The lateral size (or saying the maximum size) W3 of the openings OP3 is less than the lateral size W1 of the openings OP1 and the lateral size W2 of the openings OP2, as shown in FIG. 3. In some embodiments, the third portion 1326 of the central portion 1320 has a plurality of openings OP4 penetrating therethrough, where the openings OP4 are laterally arranged next to each (e.g., along the directions X and/or Y) and distant apart from one another. The lateral size (or saying the maximum size) W4 of the openings OP4 is less than the lateral size W1 of the openings OP1 and the lateral size W2 of the openings OP2, as shown in FIG. 3. In some embodiments, the lateral size W3 of the openings OP3 are substantially equal to the lateral size W4 of the openings OP4, as shown in FIG. 3. However, the disclosure is not limited thereto; alternatively, the lateral size W3 of the openings OP3 may be less than the lateral size W4 of the openings OP4. Or, the lateral size W3 of the openings OP3 may be greater than the lateral size W4 of the openings OP4. In some embodiments, as shown in FIG. 3, some of the openings OP3 and some of the openings OP4 are spatially communicated with the openings OP1 to form a plurality of opening holes (or openings, holes, or recesses) R2 for accommodating corresponding conductive connectors 1330 (e.g., 1332). In some embodiments, as shown in FIG. 3, some of the openings OP3 and some of the openings OP4 are spatially communicated with the openings OP2 to form a plurality of opening holes (or openings, holes, or recesses) R3 for accommodating corresponding conductive connectors 1330 (e.g., 1334).

In some embodiments, the conductive connectors 1330 includes a plurality of conductor connectors 1332 and a plurality of conductive connectors 1334, where the conductor connectors 1332 are respectively placed into the opening holes R2 so to penetrate through and be properly held by the central portion 1320, and the conductor connectors 1334 are respectively placed into the opening holes R3 so to penetrate through and be properly held by the central portion 1320. The conductive connectors 1332 each may include a body portion 1332b and two end portions 1332a, 1332c respectively connecting to two opposite sides of the body portion 1332b. As shown in FIG. 3, the body portions 1332b of the conductive connectors 1332 may be constrained inside the openings OP1 of the first portion 1322 of the central portion 1320, the end portions 1332a of the conductive connectors 1332 may be penetrated through and protruded out of the second portion 1324 of the central portion 1320 through the openings OP3, and the end portions 1332c of the conductive connectors 1332 may be penetrated through and protruded out of the third portion 1326 of the central portion 1320 through the openings OP4. In some embodiments, a gap G1 is between a sidewall of the body portion 1332b of one conductive connector 1332 and a sidewall of a respective one opening OP1, where in the top view (e.g., on the X-Y plane), the gap G1 has a lateral size D1 being greater than or substantially equal to 0. For example, the gap G1 is non-zero, as shown in FIG. 3 and FIG. 4A through FIG. 4G. The gaps G1 may be filled with air. In other words, the gaps G1 are considered as air gaps. In some embodiments, each conductive connector 1332 of the socket 1300 is disposed on (e.g., in physical contact with) and electrically connected to a respective metal trace 1226d of the circuit board structure 1200 through the end portion 1332c, where the end portion 1332a of each conductive connector 1332 is electrically connected to the object to-be-tested (e.g. the semiconductor structure 300 of FIG. 6). In some embodiments, the conductive connectors 1332 includes pogo pins or pogo probes, so to establish proper physical contacts between the end portions (e.g., 1332a, 1332c) and an overlying or underlying component (e.g., the semiconductor structure 300 or the circuit board structure 1200). Such that, an electrical connection path between the controller 200 to the socket 1300 is established. The conductive connectors 1332 are independently referred to as a signal pogo pin or a signal pogo probe.

In some embodiments, each conductive connector 1334 has an integrated structure of one paired conductive connectors (e.g., 13341, 13342) with an interface structure (e.g., 13343) interposing therebetween so to physically separate conductor connectors of the paired conductor connectors from each other. The conductive connectors 13341 and 13342 each may include a body portion 1334b and two end portions 1334a, 1334c respectively connecting to two opposite sides of the body portion 1334b. As shown in FIG. 3, the body portions 1334b of the conductive connectors 13341, 13342 may be constrained inside the openings OP2 of the first portion 1322 of the central portion 1320, the end portions 1334a of the conductive connectors 13341, 13342 may be penetrated through and protruded out of the second portion 1324 of the central portion 1320 through the openings OP3, and the end portions 1334c of the conductive connectors 13341, 13342 may be penetrated through and protruded out of the third portion 1326 of the central portion 1320 through the openings OP4. In some embodiments, a gap G2 is between a sidewall of the body portion 1334b of one conductive connector 1334 (e.g., 13341, 13342) and a sidewall of a respective one opening OP2, where in the top view (e.g., on the X-Y plane), the gap G2 has a lateral size D2 being greater than or substantially equal to 0. For example, the gap G2 is non-zero, as shown in FIG. 3 and FIG. 4A through FIG. 4G. The gaps G2 may be filled with air. In other words, the gaps G2 are considered as air gaps. In some embodiments, each conductive connector 13341, 13342 of the socket 1300 is disposed on (e.g., in physical contact with) and electrically connected to a respective metal trace 1226d of the circuit board structure 1200 through the end portion 1334c, where the end portion 1334a of each conductive connector 13341, 13342 is electrically connected to the object to-be-tested (e.g. the semiconductor structure 300 of FIG. 6). In some embodiments, the conductive connectors 13341, 13342 include pogo pins or pogo probes, so to establish proper physical contacts between the end portions (e.g., 1334a, 1334c) and an overlying or underlying component (e.g., the semiconductor structure 300 or the circuit board structure 1200). Such that, an electrical connection path between the controller 200 to the socket 1300 is established. The conductive connectors 13341 are independently referred to as a ground pogo pin or a ground pogo probe, and the conductive connectors 13342 are independently referred to as a power pogo pin or a power pogo probe; or vice versa.

In some embodiments, each of the conductive connectors 1334 includes one conductive connector 13341, one conductive connector 13342 and an interface structure 13343 inserting between and being connected to the conductive connector 13341 and the conductive connector 13342 so to separate (e.g., completely spacing apart) the conductive connector 13341 from the conductive connector 13342, see FIG. 3 and FIG. 4A through FIG. 4G. In some embodiments, the interface structure 13343 has a thickness D3 (or saying a minimum distance between the conductive connectors 13341 and 13342 in the top view (e.g., the X-Y plane)) being greater than zero and being less than or substantially equal to 500 μm, as shown in FIG. 4A. For example, the thickness D3 of the interface structure 13343 is constant. In one non-limiting example, referring to the plane view of FIG. 4A in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where an extending plane of the interface structure 13343 is substantially perpendicular to the edges of the respective one opening OP2, and a sidewall of the interface structure 13343 is flat and planar. However, the disclosure is not limited thereto. In another non-limiting example, referring to the plane view of FIG. 4B in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where an extending plane of the interface structure 13343 is not perpendicular to the edges of the respective one opening OP2, and a sidewall of the interface structure 13343 is flat and planar. In another non-limiting example, referring to the plane view of FIG. 4C in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where an extending plane of the interface structure 13343 is curved, and a sidewall of the interface structure 13343 is flat and curved (e.g. non-planar). In another non-limiting example, referring to the plane view of FIG. 4D in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where an extending plane of the interface structure 13343 has a bent angle, and a sidewall of the interface structure 13343 is bent with a sharp tip. In another non-limiting example, referring to the plane view of FIG. 4E in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where the interface structure 13343 is interdigitated with a rectangular-wave form. In another non-limiting example, referring to the plane view of FIG. 4F in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 334), where the interface structure 13343 is interdigitated with a semicircular-wave or a semielliptical-wave form. In another non-limiting example, referring to the plane view of FIG. 4G in conjunction with FIG. 3, for each conductive connector 1334, the interface structure 13343 is continuously extended from one edge of a respective one opening OP2 to an opposite edge of the respective one opening OP2 (e.g., continuously extended between two opposite side of the conductive connector 1334), where the interface structure 13343 is interdigitated with a triangular-wave form. Owing to the interface structure 13343 (e.g., the thickness D3 and the shape in the top view), the distance of the conductive connector 13341 and the conductive connector 13342 (e.g., serving as power and ground pogo pins (or probe)) is reduced and the contact area between the conductive connector 13341 and the conductive connector 13342 (e.g., serving as power and ground pogo pins (or probe)) are increased, so that a capacitive reactance between the conductive connector 13341 and the conductive connector 13342 (e.g., serving as power and ground pogo pins (or probe)) is increased, which lowers the impedance and allows better PDN. Therefore, a PI performance in the testing apparatus 1000 is improved, thereby reducing/minimizing the risk of device damage.

In some embodiments, the interface structure 13343 includes a dielectric structure 13343d, see FIG. 5A. The dielectric structure 13343d may be made of a high-k dielectric material with a dielectric constant higher than 5. High-k dielectric materials may include metal oxides. Examples of metal oxides used for high-k dielectric materials may include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. The dielectric structure 13343d may be include a dielectric film or layer. Owing to the dielectric structure 13343d (e.g., high-k dielectric material), a shorting between the conductive connector 13341 and the conductive connector 13342 (e.g., serving as power and ground pogo pins (or probe)) is prevented and parasitic capacitance is further provided, and a capacitive reactance between the conductive connector 13341 and the conductive connector 13342 (e.g., serving as power and ground pogo pins (or probe)) is increased, which lowers the impedance and allows better PDN. Therefore, a PI performance in the testing apparatus 1000 is improved, thereby reducing/minimizing the risk of device damage. In such embodiments, each of the conductive connectors 1334 may be formed, but not limited to, by the following steps: forming an initial structure having the conductive connectors 13341 and 13342 sharing the same body portion 1334b; patterning the initial structure to completely separate the conductive connector 13341 form the conductive connector 13342 by forming a recess (or hole) penetrating through the body portion 1334b being shared therebetween; and deposit the high-k dielectric material to fill the recess (or hole) so to form the dielectric structure 13343d between the conductive connectors 13341 and 13342, thereby forming one conductive connector 1334. Or, in such embodiments, each of the conductive connectors 1334 may be formed, but not limited to, by the following steps: providing two independent and separate conductive connectors 13341 and 13342; forming a blanket layer of the high-k dielectric material on one of the body portions 1334b of the conductive connectors 13341 and 13342 so to form the dielectric structure 13343d; and bonding the body portions 1334b of the conductive connectors 13341 and 13342 to each other through the dielectric structure 13343d. However, the disclosure is not limited thereto.

In some embodiments, the interface structure 13343 includes a capacitor structure 13343c, see FIG. 5B. The capacitor structure 13343c may include one or more than one capacitor. The capacitor may be in form of a cube or in form of a column. If considering the capacitor structure 13343c includes a plurality of capacitors (e.g., in cubic form), the capacitors are arranged into an array, and each of the capacitors is interposed between the conductive connector 13341 and the conductive connector 13342 to separate the conductive connector 13341 and the conductive connector 13342. If considering the capacitor structure 13343c includes a plurality of capacitors (e.g., in columnar form), the capacitors are arranged parallel to each other (e.g., along a short edge of the body portions 1334b, along a long edge of the body portions 1334b, or along a direction not parallel to a short edge and a long edge of the body portions 1334b), and each of the capacitors is interposed between the conductive connector 13341 and the conductive connector 13342 to separate the conductive connector 13341 and the conductive connector 13342. For example, as shown in FIG. 5B, the capacitors are separated from each other by a gap G. The gap G may be an air gap. Owing to the capacitor structure 13343c, a directly embedded capacitor(s) between the conductive connector 13341 and the conductive connector 13342 (e.g., serving as power and ground pogo pins (or probe)) is obtained, and thus a capacitive reactance between the conductive connector 13341 and the conductive connector 13342 (e.g., serving as power and ground pogo pins (or probe)) is increased, which lowers the impedance and allows better PDN. Therefore, a PI performance in the testing apparatus 1000 is improved, thereby reducing/minimizing the risk of device damage.

The number of the conductive connectors 1332 and 1334 included in the socket 1300 are not limited to the drawings of the disclosure, and may be selected and designated based on the demand and the design requirement/layout. The disclosure is not limited thereto. One pair of the conductive connector 13341 and the conductive connector 13342 may be referred to as a paired power/ground pin (or probe), a paired power/ground pogo pin (or probe), a power/ground pin (or probe) paring structure or a power/ground pogo pin (or probe) paring structure. The conductive connectors 1332 and 1334 of the conductive connectors 1330 are electrically isolated from the central portion 1320, for example.

In some embodiments, the socket 1300 is installed onto the circuit board structure 1200 through the holding element 1100. For example, the holding element 1100 includes a plurality of blots, as shown in FIG. 2 and FIG. 3. In some embodiments, the holding element 1100 penetrate through the socket 1300 (e.g., the flange portion 1310) through openings 1300a and further extended into the circuit board structure 1200, where the holding element 1100 is threaded into and tightened to the circuit board structure 1200. However, the disclosure is not limited thereto; alternatively, a socket adopter (not shown) may be installed onto the surface S1200 of the circuit board structure 1200, where the socket adopter is configured to engage with the socket 1300 and allows the socket 1300 being electrically connected to the circuit board structure 1200 underlying thereto. In such alternative embodiments, the holding element 1100 may be omitted.

The cover 1400 may be disposed on the socket 1300, as shown in FIG. 3. For example, the cover 1400 is in direct contact with the flange portion 1310 of the socket 1300, where the socket 1300 is disposed between the circuit board structure 1200 and the cover 1400. In some embodiments, the cover 1400 is made of a dielectric material or a combination of a dielectric material and a conductive material, the disclosure is not limited thereto, as long as the cover 1400 is not electrically short with the socket 1300 (e.g., the conductive connectors 1330) and the object to-be-test (e.g., the semiconductor structure 300 of FIG. 6). For example, conductive material includes a metallic material, such as a metal or a metal alloy. In some embodiments, a dielectric material is capable of providing a specific stiffness that ensuring the physical and mechanical strength of the cover 1400. The stiffness (which may be quantified by its Yong's modulus) can be in the range of about 10 GPa to about 30 GPa. For example, the cover 1400 is removably placed onto the socket 1300, which facilitates the placement of the object to-be-test (e.g., the semiconductor structure 300 of FIG. 6).

In some embodiments, a semiconductor structure is installed onto the testing apparatus, in accordance with step S12 of the method 10 depicted in FIG. 1. For example, as shown in FIG. 3 and FIG. 6, the semiconductor structure 300, which is referred to as the object to-be-tested as previously mentioned, is provided and placed into the space R1 confined by the socket 1300 and the cover 1400 and is electrically coupled to the testing apparatus 1000 through contacting conductive pads 320 of the semiconductor structure 300 and the conductive connectors 1330 of the socket 1300 to construct the assembly of the testing apparatus 1000 and the semiconductor structure 300. It is appreciated that, some of the conductive pads 320 of the semiconductor structure 300 are assigned as signal pads (which corresponding to the conductive connectors 1332 of the conductive connectors 1330 included in the socket 1300), some of the conductive pads 320 of the semiconductor structure 300 are assigned as ground pads (which corresponding to the conductive connectors 13341 of the conductive connectors 1330 included in the socket 1300), and some of the conductive pads 320 of the semiconductor structure 300 are assigned as power pads (which corresponding to the conductive connectors 13342 of the conductive connectors 1330 included in the socket 1300), depending on the demand and design requirement/layout. In the disclosure, the semiconductor structure 300 is at a chip-level (e.g., as a final product after packaging). For example, the semiconductor structure 300 is may be a package-on-package (PoP), a system-on-chip (SoC), a system-on-integrated-circuit (SoIC) device, an integrated fan-out package, a chip-on wafer package, or a chip-on wafer-on-substrate package, or the like. Since there are various and numerous types of the semiconductor structure 300 could be chosen, the disclosure does not limit the type of the semiconductor structure 300, as long as the semiconductor structure 300 is at chip-level with sufficient components to perform the designated propose; thus, the detailed structure of the semiconductor structure 300 is omitted for brevity. With such electrical connections between the testing apparatus 1000 and the semiconductor structure 300, the semiconductor structure 300 is prepared to be tested by using the testing apparatus 1000, for example.

In some embodiments, a test sequence (such as an automated test sequence) is performed on the semiconductor structure through the testing apparatus, in accordance with step S13 of the method 10 depicted in FIG. 1. In a testing method using the testing apparatus 1000, an assembly (including the testing apparatus 1000, the semiconductor structure 300, the controller 200 and the testing circuit structure 100) may have several possible testing electrical transmitting paths to test the semiconductor structure 300. For example, a testing electrical transmitting path is discussed below for illustrative purposes, however the disclosure is not limited herein. In a non-limiting example, an electric signal (e.g., a testing electric signal) is sent from the controller 200 to the semiconductor structure 300 by way of the testing circuit structure 100, the circuit board structure 1200, and the conductive connectors 1330 of the socket 1300; and the electric signal (e.g., the responsive electric signal, sometimes referred to as a loopback (feedback) signal) is sent from the semiconductor structure 300 to the controller 200 by way of the above components in the reversed order (e.g., the conductive connectors 1330 of the socket 1300, the circuit board structure 1200, and the testing circuit structure 100). If there is a circuit fault or electrical fault in the circuitry inside the semiconductor structure 300, then the electric signals attempting to traverse the above-described path would not be able to reach to the controller 200 or an abnormal electric signals attempting to traverse the above-described path would be received by the controller 200. After analyzing the result by the controller 200, the status of the semiconductor structure 300 will be determined.

In the above embodiments of the testing apparatus 1000, the socket 1300 and the circuit board structure 1200 are in a one-to-one configuration. However, the disclosure is not limited thereto; alternatively, for the testing apparatus 1000 in the disclosure, the socket 1300 and the circuit board structure 1200 may be in a multiple-to-one configuration, such as a 2-to-1 configuration, a 3-to-1 configuration, a 4-to-1 configuration, or so on. In some embodiments, the socket 1300 and the semiconductor structure 300 are in a one-to-one configuration.

In the above embodiments, the testing apparatus 1000 is adopted for testing the semiconductor structure of chip-level (e.g., as a final product after packaging) in the method 10 of FIG. 1, however the disclosure is not limited thereto. A testing apparatus (e.g., 2000) may be adopted for testing the semiconductor structure of wafer-level, in the disclosure.

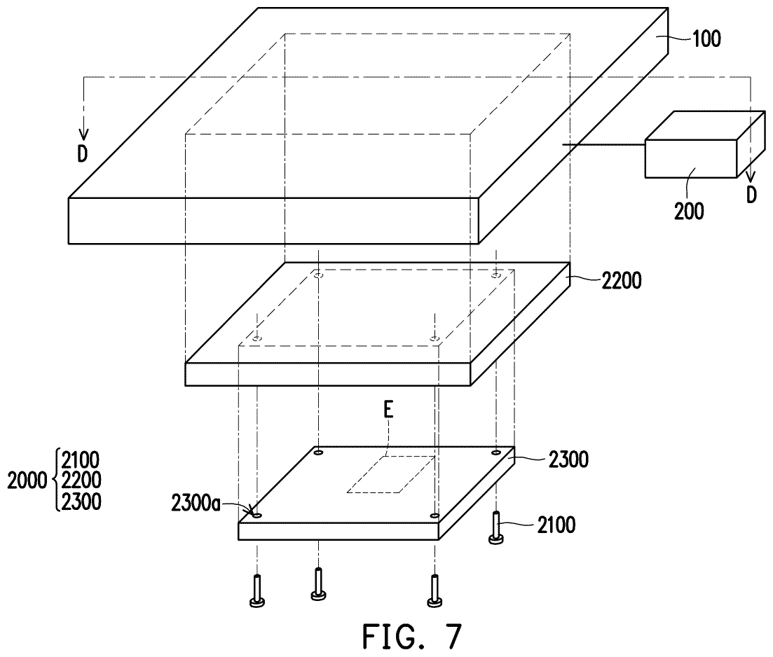

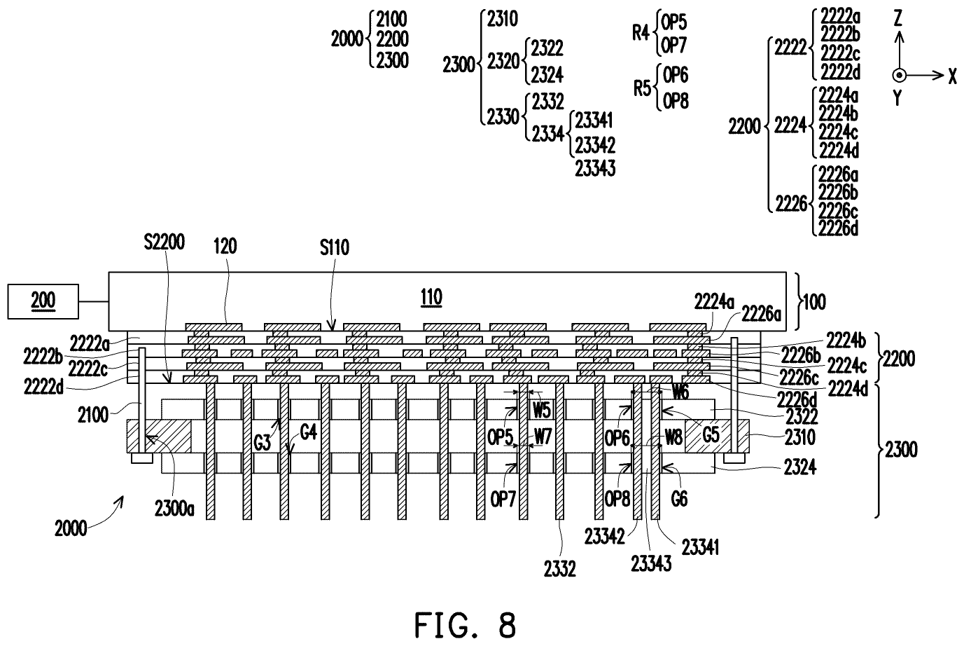

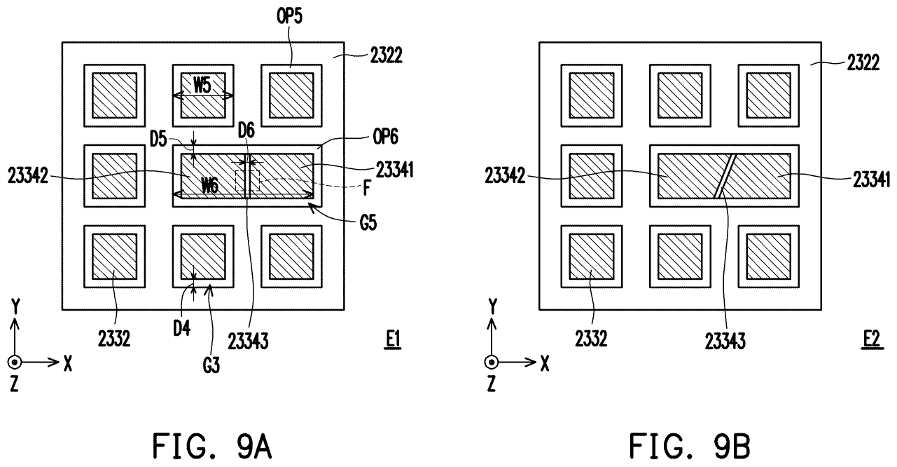

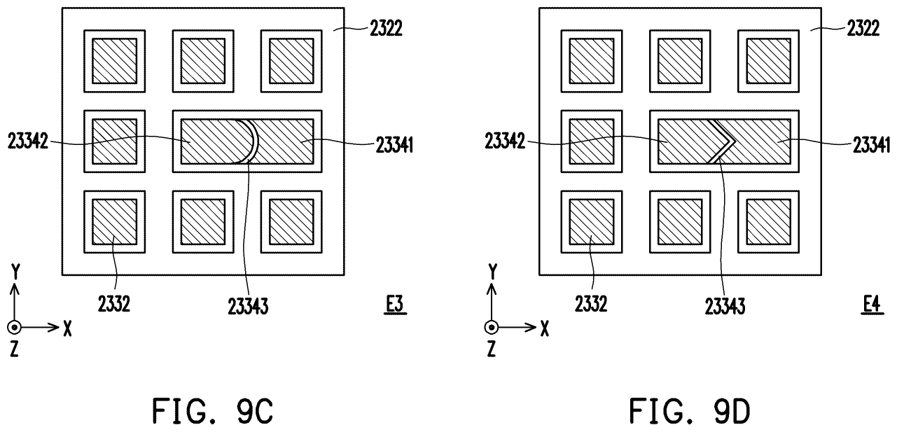

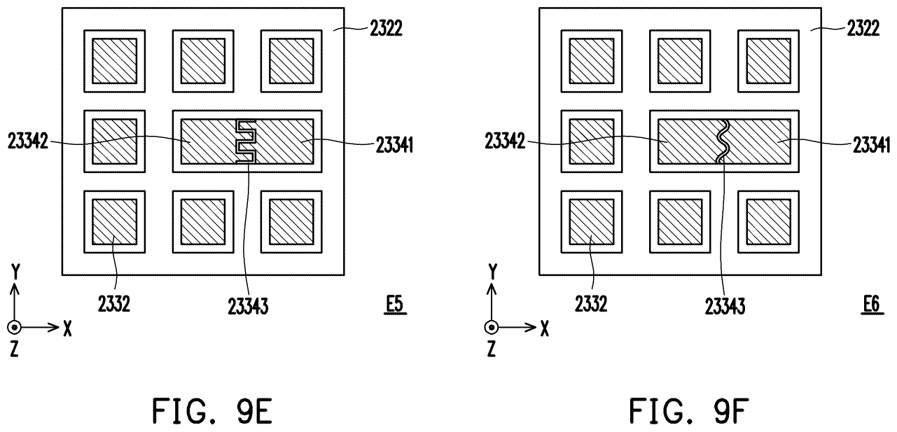

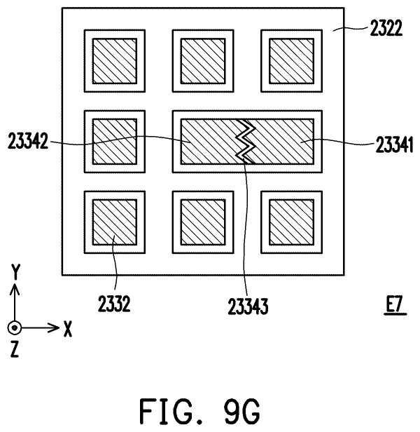

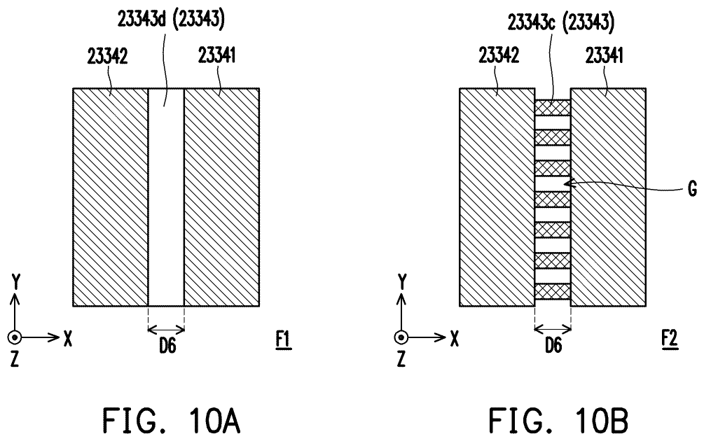

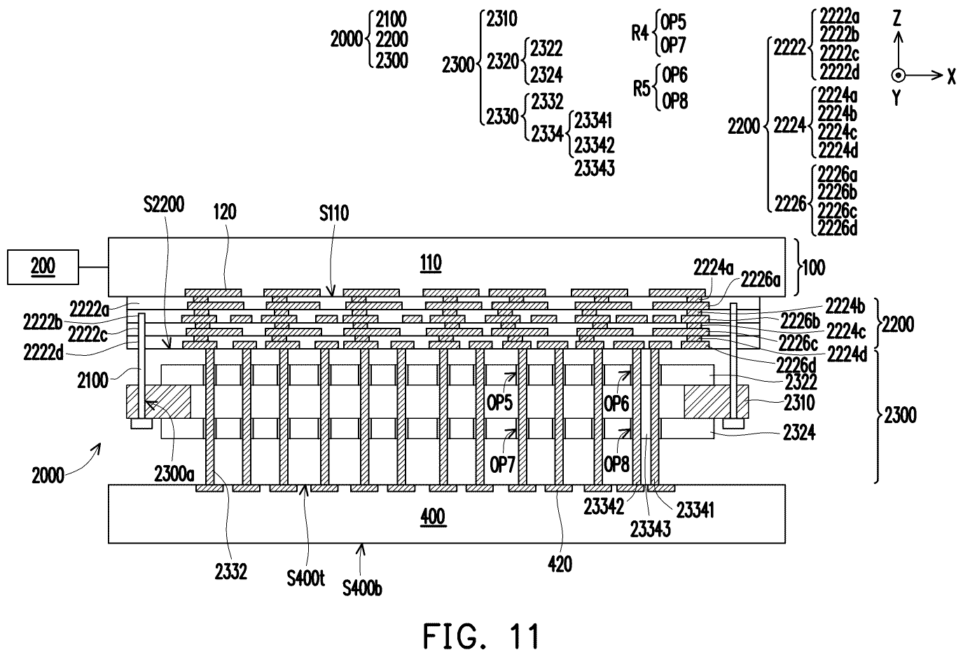

FIG. 7 is a schematic explosive view illustrating a testing apparatus (e.g., 2000) in accordance with some embodiments of the disclosure. FIG. 8 is a schematic cross-sectional view of the testing apparatus (e.g., 2000) depicted in FIG. 7, where FIG. 8 is a cross-sectional view taken along a line D-D depicted in FIG. 7. FIG. 9A through FIG. 9G are schematic, enlarged plane views respectively showing various embodiments of a configuration of testing pins (e.g., 2330) in a central portion (e.g., 2320) of a portion of a socket (e.g., 2300) included in the testing apparatus (e.g., 2000) depicted in FIG. 7, which are outlined by a dashed-box E depicted in FIG. 7 (e.g., a dashed-box E1 in FIG. 9A, a dashed-box E2 in FIG. 9B, a dashed-box E3 in FIG. 9C, a dashed-box E4 in FIG. 9D, a dashed-box E5 in FIG. 9E, a dashed-box E6 in FIG. 9F and/or a dashed-box E7 in FIG. 9G). FIG. 10A through FIG. 10B are schematic, enlarged plane views respectively showing various embodiments of a configuration of a pair of power and ground pins (e.g., 23341, 23342) in the testing apparatus (e.g., 2000) depicted in FIG. 7, which are outlined by a dashed-box F depicted in FIG. 9A (e.g., a dashed-box F1 in FIG. 10A and/or a dashed-box F2 in FIG. 10B). FIG. 11 is a schematic cross-sectional view of an assembly of a testing apparatus (e.g., 2000) and a semiconductor structure (e.g., 400) in accordance with some embodiments of the disclosure. The embodiments are intended to provide further explanations, but are not used to limit the scope of the disclosure. The elements similar to or substantially the same as the elements described previously will use the same reference numbers, and certain details or descriptions (e.g., the materials, formation processes, positioning configurations, etc.) of the same elements would not be repeated herein.

In some embodiments, a testing apparatus is provided, in accordance with step S11 of the method 10 depicted in FIG. 1. Referring to FIG. 7 and FIG. 8, in some embodiments, a testing apparatus 2000 is provided, where a testing circuit structure 100 is placed on and electrically coupled to the testing apparatus 2000, and the testing circuit structure 100 is further electrically coupled to a controller 200. In other words, the testing apparatus 2000 is electrically coupled to the controller 200 through the testing circuit structure 100. The details of the testing circuit structure 100 and the controller 200 have been previously discussed in FIG. 2 through FIG. 6, and thus are not repeated herein for brevity.

For example, the testing apparatus 2000 includes a holding element 2100, a circuit board structure 2200 (including dielectric layers 2222 (e.g., 2222a, 2222b, 2222c, 2222d), metal vias 2224 (e.g., 2224a, 2224b, 2224c, 2224d) and metallization traces 2226 (e.g., 2226a, 2226b, 2226c, 2226d)), and a socket 2300. In some embodiments, the circuit board structure 2200 is disposed on and electrically connected to the socket 2300, and the holding element 2100 penetrates through the socket 2300 via openings 2300a and further extended into the circuit board structure 2200 so to lock the socket 2300 onto the circuit board structure 2200. As shown in FIG. 8, for example, the testing circuit structure 100 is disposed on the circuit board structure 2200 of the testing apparatus 2000, and is electrically coupled to the circuit board structure 2200 through physically contacting conductive contacts 120 of the testing circuit board 100 and the metal vias 2224a of the circuit board structure 2200. In other words, the circuit board structure 2200 is disposed between and electrically couples the testing circuit structure 100 and the socket 2300. The formations and materials of the holding element 2100 and circuit board structure 2200 (including dielectric layers 2222 (e.g., 2222a, 2222b, 2222c, 2222d), metal vias 2224 (e.g., 2224a, 2224b, 2224c, 2224d) and metallization traces 2226 (e.g., 2226a, 2226b, 2226c, 2226d)) are substantially identical or similar to the formations and materials of the holding element 1100 and circuit board structure 1200 (including dielectric layers 1222 (e.g., 1222a, 1222b, 1222c, 1222d), metal vias 1224 (e.g., 1224a, 1224b, 1224c, 1224d) and metallization traces 1226 (e.g., 1226a, 1226b, 1226c, 1226d)), and thus are not repeated herein for brevity.

In some embodiments, the circuit board structure 2200 is in physical contact with the testing circuit structure 100 (e.g., a surface S110), as shown in FIG. 8. The metal trace 2226a, the metal via 2224a and the dielectric layer 2222a together constitute a first build-up layer; the metal trace 2226b, the metal via 2224b and the dielectric layer 2222b together constitute a second build-up layer; the metal trace 2226c, the metal via 2224c and the dielectric layer 2222c together constitute a third build-up layer; and, the metal trace 2226d, the metal via 2224d and the dielectric layer 2222d together constitute a fourth build-up layer. For example, the metal via 2224a connects the metal trace 2226a underlying thereto and the conductive contacts 120 respectively overlying thereto, and the metal traces 2226a and the respective conductive contacts 120 are electrically connected to each other through the metal via 2224a. The metal via 2224b connects the metal trace 2226b underlying thereto and the metal trace 2226a overlying thereto, and the metal traces 2226a and 2226b are electrically connected to each other through the metal via 2224b. The metal via 2224c connects the metal trace 2226c underlying thereto and the metal trace 2226b overlying thereto, and the metal traces 2226b and 2226c are electrically connected to each other through the metal via 2224c. The metal via 2224d connects the metal trace 2226d underlying thereto and the metal trace 2226c overlying thereto, and the metal traces 2226c and 2226d are electrically connected to each other through the metal via 2224d. That is, the electrical connection paths between the metal traces 2226d and the metal vias 2224a are established. Owing to such configuration, the metal traces 2226 and the metal vias 2224 together constitute a routing structure, thereby the circuit board structure 2200 is capable of providing a routing function. Only four build-up layers are shown in the disclosure for illustrative proposes only, and the disclosure is not limited thereto. The number of the build-up layers included in the circuit board structure 2200 may be selected and designated based on the demand and design requirement/layout.

As shown in FIG. 8, the circuit board structure 2200 may be electrically connected to the testing circuit structure 100 through the metal vias 2224 (e.g., 2224a). However, the disclosure is not limited thereto; alternatively, additional (conductive or electrical) connectors (not shown) may be presented between the metal vias 2224a of the circuit board structure 2200 and the conductive contacts 120 of the testing circuit structure 100 to obtain proper electrical connections therebetween.

In other words, the electric signals generated from the controller 200 may be rerouted to the sockets 2300 through the testing circuit board 100 and the circuit board structure 2200 for testing the object to-be-tested, and/or the responsive electric feedbacked from the object to-be-tested being received by the socket 2300 may be rerouted to the controller 200 through testing circuit board 100 and the circuit board structure 2200 for further processing. In certain embodiments, the circuit board structure 2200 sometimes may be referred to as a loadboard for the socket 2300, where a variety of electrical components/devices (such as integrated circuits, resistors, capacitors, inductors, relays, etc.) are employed to make up the loadboard's test circuit. However, the disclosure is not limited thereto, in alternative embodiments, the circuit board structure 2200 serves as a loadboard for the socket 2300, which is free of additional electrical components/devices.

In addition, the circuit board structure 2200 may be properly secured onto the testing circuit structure 100 by a holding element (not shown), where the holding element may be a fastener (e.g., blots or blots threaded with nuts, with or without washer), a clamp, an adhesive e.g., made of dielectric material, a metallic material, or a combination thereof), or the like, the disclosure is not limited thereto, as long as the placement of the circuit board structure 2200 over the testing circuit structure 100 is properly secured. For example, as shown in FIG. 8, the circuit board structure 2200 directly contacts the surface S110 of the testing circuit structure 100.

In some embodiments, the socket 2300 is disposed over and electrically coupled to the circuit board structure 2200. Back to FIG. 7 through FIG. 8, in some embodiments, the socket 2300 is in physical contact with the circuit board structure 2200 (e.g. a surface S2200 of the circuit board structure 2200). For example, the socket 2300 includes a flange portion 2310, a central portion 2320, and a plurality of conductive connectors 2330 penetrating through the central portion 2320. In some embodiments, the flange portion 2310 is disposed over (e.g., spatially spacing apart from) and electrically isolated from the circuit board structure 2200, and the central portion 2320 is disposed over (e.g., spatially spacing apart from) and electrically isolated from the circuit board structure 2200. As shown in FIG. 8, the conductive connectors 2330 may be directly stand on (e.g., directly prop against) the surface S2200 of the circuit board structure 2200, where the conductive connectors 2330 may be in physical contact with the metal vias 2224a of the circuit board structure 2200 so to electrically coupled to the circuit board structure 2200.

In some embodiments, the flange portion 2310 is connected to the central portion 2320, where the flange portion 2310 is at a periphery of the central portion 2320. For example, the flange portion 2310 is overlapped with the central portion 2320 at the periphery of the central portion 2320. In some embodiment, the central portion 2320 includes a first portion 2322 and a second portion 2324, where the first portion 2322 and the second portion 2324 are respectively disposed at two opposite sides of the flange portion 2310. In other words, the flange portion 2310 is interposed between the first portion 2322 and the second portion 2324. In a top view (e.g., the X-Y plane) along the direction Z (e.g., a stacking direction of the socket 2300 and the circuit board structure 2200 of the testing apparatus 2000), the central portion 2320 may be in a circle-shape, for example. However, the disclosure is not limited thereto; alternatively, in the top view along the direction Z, the central portion 2320 may be in a square-shape, a rectangular shape, an ellipse-shape, or any suitable polygonal shape. In some embodiments, in the top view along the direction Z, the first portion 2322 and the second portion 2324 of the central portion 2320 have the same shape and dimension. The flange portion 2310 is in an annular form, such as a (continuously) ring shape in the top view, for example. In some embodiments, in the top view along the direction Z, the shape of the flange portion 2310 corresponds to the shape of the central portion 2320.

In some embodiments, the flange portion 2310 is made of a material with a sufficient stiffness (which may be quantified by its Yong's modulus) for protecting and supporting elements (e.g., the conductive connectors 2330 and/or the central portion 2310) disposed thereon/therein. The material of the flange portion 2310 may include a conductive material, a dielectric material or a combination of dielectric material and conductive material. For example, the conductive material includes a metallic material (such as a metal or a metal alloy). The material of the flange portion 2310 may include stainless steel, polyester, polyimide, glass, epoxy, or the like. In some embodiments, the material of the central portion 2320 include a dielectric material capable of providing a specific stiffness that ensuring the physical and mechanical strength of the sockets 2300. The stiffness (which may be quantified by its Yong's modulus) can be in the range of about 10 GPa to about 30 GPa. In some embodiments, the central portion 2320 is made of ceramic or the like. For example, In some embodiments, the materials of the first portion 2322 and the second portion 2324 of the central portion 2320 are the same, such as ceramic. The disclosure is not limited thereto. Alternatively, the materials of the first portion 2322 and the second portion 2324 may be different. The flange portion 2310 is electrically isolated from the central portion 2320, for example.

The first portion 2322 may be referred to as a top lid (structure), a top cap (structure) or a top die (structure) of the central portion 2320, and the second portion 2324 may be referred to as a bottom lid (structure), a bottom cap (structure) or a bottom die (structure) of the central portion 2320. In some embodiments, the first and second portions (2322, 2324) of the central portion 2320 are used to hold the conductive connectors 2330 in proper position inside the socket 2300. In addition, the first portion 2322 and the second portion 2324 of the central portion 2330 may be properly secured onto the flange portion 2310 by a holding element (not shown), where the holding element may be a fastener (e.g., blots or blots threaded with nuts, with or without washer), a clamp, an adhesive e.g., made of dielectric material, a metallic material, or a combination thereof), or the like. The disclosure is not limited thereto, as long as the placements of the first portion 2322 and the second portion 2324 over the flange portion 2310 are properly secured.

Continued on FIG. 8, the first portion 2322 of the central portion 2320 has a plurality of openings OP5 and a plurality of openings OP6 penetrating therethrough, where the openings OP5 and the openings OP6 are laterally arranged next to each (e.g., along the directions X and/or Y) and distant apart from one another. In some embodiments, in the top view (e.g., the X-Y plane), the openings OP5 has a lateral size (or saying a maximum size) W5 being less than a lateral size (or saying a maximum size) W6 of the openings OP6, as shown in FIG. 8 and FIG. 9A. In some embodiments, the second portion 2324 of the central portion 2320 has a plurality of openings OP7 and a plurality of openings OP8 penetrating therethrough, where the openings OP7 and the openings OP8 are laterally arranged next to each (e.g., along the directions X and/or Y) and distant apart from one another. In some embodiments, the openings OP7 has a lateral size (or saying a maximum size) W7 being less than a lateral size (or saying a maximum size) W8 of the openings OP8, as shown in FIG. 8. The lateral size (or saying the maximum size) W5 of the openings OP5 may be substantially equal to the lateral size (or saying the maximum size) W7 of the openings OP7, as shown in FIG. 8. On the other hand, the lateral size (or saying the maximum size) W6 of the openings OP6 may be substantially equal to the lateral size (or saying the maximum size) W8 of the openings OP8, as shown in FIG. 8. In some embodiments, as shown in FIG. 8, the openings OP5 and respective openings OP7 (e.g., being directly underneath thereto) are spatially communicated to each other through a space confined by the flange portion 2310 and the central portion 2320, and so to form a plurality of opening holes (or openings, holes, or recesses) R4 for accommodating corresponding conductive connectors 2330 (e.g., 2332). In some embodiments, as shown in FIG. 8, the openings OP6 and respective openings OP8 (e.g., being directly underneath thereto) are spatially communicated to each other through a space confined by the flange portion 2310 and the central portion 2320, and so to form a plurality of opening holes (or openings, holes, or recesses) R5 for accommodating corresponding conductive connectors 2330 (e.g., 2334).

In some embodiments, the conductive connectors 2330 includes a plurality of conductor connectors 2332 and a plurality of conductive connectors 2334, where the conductor connectors 2332 are respectively placed into the opening holes R4 so to penetrate through and be properly held by the central portion 2320, and the conductor connectors 2334 are respectively placed into the opening holes R5 so to penetrate through and be properly held by the central portion 2320. In addition, the conductive connectors 2330 (e.g., 2332, 2334) may be properly held by the central portion 2320 through a microstructure (not shown) being formed on sidewalls of the conductive connectors 2330, where the microstructure is capable of removably engaging the conductive connectors 2330 to the central portion 2320. It is appreciated that the microstructure(s) may be selected and designate based on the demand and design requirement/layout, and thus is not limited in the disclosure.

The conductive connectors 2332 may penetrate through the first portion 2322 and the second portion 2324 of the central portion 2300 via the opening holes R4 and each may have two opposite end portions respectively protruding out of the first portion 2322 and the second portion 2324, shown in FIG. 8. In some embodiments, a gap G3 is between a sidewall of each of the conductive connectors 2332 and a sidewall of a respective one opening OP5, where in the top view (e.g., the X-Y plane), the gap G3 has a lateral size D4 being greater than or substantially equal to 0. For example, the gap G3 is non-zero, as shown in FIG. 8 and FIG. 9A through FIG. 9G. The gaps G3 may be filled with air. In other words, the gaps G3 are considered as air gaps. On the other hand, a gap G4 is between a sidewall of each of the conductive connectors 2332 and a sidewall of a respective one opening OP7, where the gap G4 has a lateral size being greater than or substantially equal to 0, as shown in FIG. 8. For example, the gap G4 is non-zero. The gaps G4 may be filled with air. In other words, the gaps G4 are considered as air gaps. In some embodiments, one end portion of each conductive connector 2332 of the socket 2300 is in physical contact with and electrically connected to a respective metal trace 2226d of the circuit board structure 2200, and other end portion of each conductive connector 2332 of the socket 2300 is in physical contact with and electrically connected to the object to-be-tested (e.g. the semiconductor structure 400 of FIG. 11). In some embodiments, the conductive connectors 2332 includes MEMS pins or MEMS probes, so to establish proper physical contacts between the end portions and an overlying or underlying component (e.g., the semiconductor structure 400 or the circuit board structure 2200). Such that, an electrical connection path between the controller 200 to the socket 2300 is established. The conductive connectors 2332 are independently referred to as a signal MEMS pin or a signal MEMS probe.

In some embodiments, each conductive connector 2334 has an integrated structure of one paired conductive connectors (e.g., 23341, 23342) with an interface structure (e.g., 23343) interposing therebetween so to physically separate conductor connectors of the paired conductor connectors from each other. The conductive connectors 23341 and 23342 each may penetrate through the first portion 2322 and the second portion 2324 of the central portion 2300 via the opening holes R5 and each may have two opposite end portions respectively protruding out of the first portion 2322 and the second portion 2324, shown in FIG. 8. In some embodiments, a gap G5 is between a sidewall of each of the conductive connectors 2334 (e.g., 23341, 23342) and a sidewall of a respective one opening OP6, where in the top view (e.g., the X-Y plane), the gap G5 has a lateral size D5 being greater than or substantially equal to 0. For example, the gap G5 is non-zero, as shown in FIG. 8 and FIG. 9A through FIG. 9G. The gaps G5 may be filled with air. In other words, the gaps G5 are considered as air gaps. On the other hand, a gap G6 is between a sidewall of each of the conductive connectors 2334 (e.g., 23341, 23342) and a sidewall of a respective one opening OP8, where the gap G6 has a lateral size being greater than or substantially equal to 0, as shown in FIG. 8. For example, the gap G6 is non-zero. The gaps G6 may be filled with air. In other words, the gaps G6 are considered as air gaps. In some embodiments, one end portion of each conductive connector 23341, 23342 of the socket 2300 is in physical contact with and electrically connected to a respective metal trace 2226d of the circuit board structure 2200, and other end portion of each conductive connector 23341, 23342 of the socket 2300 is in physical contact with and electrically connected to the object to-be-tested (e.g. the semiconductor structure 400 of FIG. 11). In some embodiments, the conductive connectors 23341, 23342 include MEMS pins or MEMS probes, so to establish proper physical contacts between the end portions of the conductive connections 2334 and an overlying or underlying component (e.g., the semiconductor structure 400 or the circuit board structure 2200). Such that, an electrical connection path between the controller 200 to the socket 2300 is established. The conductive connectors 23341 are independently referred to as a ground MEMS pin or a ground MEMS probe, and the conductive connectors 23342 are independently referred to as a power MEMS pin or a power MEMS probe; or vice versa.

In some embodiments, each of the conductive connectors 2334 includes one conductive connector 23341, one conductive connector 23342 and an interface structure 23343 inserting between and being connected to the conductive connector 23341 and the conductive connector 23342 so to separate (e.g., completely spacing apart) the conductive connector 23341 from the conductive connector 23342, see FIG. 8 and FIG. 9A through FIG. 9G. In some embodiments, the interface structure 23343 has a thickness D6 (or saying a minimum distance between the conductive connectors 23341 and 23342 in the top view (e.g., the X-Y plane)) being greater than zero and being less than or substantially equal to 500 μm, as shown in FIG. 9A. For example, the thickness D6 of the interface structure 23343 is constant. In one non-limiting example, referring to the plane view of FIG. 9A in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where an extending plane of the interface structure 23343 is substantially perpendicular to the edges of the respective openings OP6, OP8, and a sidewall of the interface structure 13343 is flat and planar. However, the disclosure is not limited thereto. In another non-limiting example, referring to the plane view of FIG. 9B in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where an extending plane of the interface structure 23343 is not perpendicular to the edges of the respective one openings OP6, OP8, and a sidewall of the interface structure 13343 is flat and planar. In another non-limiting example, referring to the plane view of FIG. 9C in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where an extending plane of the interface structure 23343 is curved, and a sidewall of the interface structure 23343 is flat and curved (e.g. non-planar). In another non-limiting example, referring to the plane view of FIG. 9D in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where an extending plane of the interface structure 23343 has a bent angle, and a sidewall of the interface structure 23343 is bent with a sharp tip. In another non-limiting example, referring to the plane view of FIG. 9E in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where the interface structure 23343 is interdigitated with a rectangular-wave form. In another non-limiting example, referring to the plane view of FIG. 9F in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where the interface structure 23343 is interdigitated with a semicircular-wave or a semielliptical-wave form. In another non-limiting example, referring to the plane view of FIG. 9G in conjunction with FIG. 8, for each conductive connector 2334, the interface structure 23343 is continuously extended from one edge of a respective one opening OP6 to an opposite edge of the respective one opening OP6 and from one edge of a respective one opening OP8 to an opposite edge of the respective one opening OP8 (e.g., continuously extended between two opposite side of the conductive connector 2334), where the interface structure 23343 is interdigitated with a triangular-wave form. Owing to the interface structure 23343 (e.g., the thickness D6 and the shape in the top view), the distance of the conductive connector 23341 and the conductive connector 23342 (e.g., serving as power and ground MEMS pins (or probe)) is reduced and the contact area between the conductive connector 23341 and the conductive connector 23342 (e.g., serving as power and ground MEMS pins (or probe)) are increased, so that a capacitive reactance between the conductive connector 23341 and the conductive connector 23342 (e.g., serving as power and ground MEMS pins (or probe)) is increased, which lowers the impedance and allows better PDN. Therefore, a PI performance in the testing apparatus 2000 is improved, thereby reducing/minimizing the risk of device damage.

In some embodiments, the interface structure 23343 includes a dielectric structure 23343d, see FIG. 10A. The dielectric structure 23343d may be made of a high-k dielectric material with a dielectric constant higher than 5. High-k dielectric materials may include metal oxides. Examples of metal oxides used for high-k dielectric materials may include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. The dielectric structure 23343d may be include a dielectric film or layer. Owing to the dielectric structure 23343d (e.g., high-k dielectric material), a shorting between the conductive connector 23341 and the conductive connector 23342 (e.g., serving as power and ground MEMS pins (or probe)) is prevented and parasitic capacitance is further provided, and a capacitive reactance between the conductive connector 23341 and the conductive connector 23342 (e.g., serving as power and ground MEMS pins (or probe)) is increased, which lowers the impedance and allows better PDN. Therefore, a PI performance in the testing apparatus 2000 is improved, thereby reducing/minimizing the risk of device damage. In such embodiments, each of the conductive connectors 2334 may be formed, but not limited to, by the following steps: forming an initial structure having the conductive connectors 23341 and 23342 interconnected to each other; patterning the initial structure to completely separate the conductive connector 23341 form the conductive connector 23342 by forming a recess (or hole) completely penetrating through the initial structure; and deposit the high-k dielectric material to fill the recess (or hole) so to form the dielectric structure 23343d between a portion of the conductive connector 23341 and a portion of the conductive connector 23342, thereby forming one conductive connector 2334. Or, in such embodiments, each of the conductive connectors 2334 may be formed, but not limited to, by the following steps: providing two independent and separate conductive connectors 23341 and 23342; forming a blanket layer of the high-k dielectric material on one of a portion of the conductive connectors 23341 and 23342 so to form the dielectric structure 23343d; and bonding the conductive connectors 23341 and 23342 to each other through the dielectric structure 23343d. However, the disclosure is not limited thereto.

In some embodiments, the interface structure 23343 includes a capacitor structure 23343c, see FIG. 10B. The capacitor structure 23343c may include one or more than one capacitor. The capacitor may be in form of a cube or in form of a column. If considering the capacitor structure 23343c includes a plurality of capacitors (e.g., in cubic form), the capacitors are arranged into an array, and each of the capacitors is interposed between the conductive connector 23341 and the conductive connector 23342 to separate the conductive connector 23341 and the conductive connector 23342. If considering the capacitor structure 23343c includes a plurality of capacitors (e.g., in columnar form), the capacitors are arranged parallel to each other, and each of the capacitors is interposed between the conductive connector 23341 and the conductive connector 23342 to separate the conductive connector 23341 and the conductive connector 23342. For example, as shown in FIG. 10B, the capacitors are separated from each other by a gap G. The gap G may be an air gap. Owing to the capacitor structure 23343c, a directly embedded capacitor(s) between the conductive connector 23341 and the conductive connector 23342 (e.g., serving as power and ground MEMS pins (or probe)) is obtained, and thus a capacitive reactance between the conductive connector 23341 and the conductive connector 23342 (e.g., serving as power and ground MEMS pins (or probe)) is increased, which lowers the impedance and allows better PDN. Therefore, a PI performance in the testing apparatus 2000 is improved, thereby reducing/minimizing the risk of device damage.

The number of the conductive connectors 2332 and 2334 included in the socket 2300 are not limited to the drawings of the disclosure, and may be selected and designated based on the demand and the design requirement/layout. The disclosure is not limited thereto. One pair of the conductive connector 23341 and the conductive connector 23342 may be referred to as a paired power/ground pin (or probe), a paired power/ground MEMS pin (or probe), a power/ground pin (or probe) paring structure or a power/ground MEMS pin (or probe) paring structure. The conductive connectors 2332 and 2334 of the conductive connectors 2330 are electrically isolated from the central portion 2320, for example.

In some embodiments, the socket 2300 is installed onto the circuit board structure 2200 through the holding element 2100. For example, the holding element 2100 includes a plurality of blots, as shown in FIG. 7 and FIG. 8. In some embodiments, the holding element 2100 penetrate through the socket 2300 (e.g., the flange portion 2310) through openings 2300a and further extended into the circuit board structure 2200, where the holding element 2100 is threaded into and tightened to the circuit board structure 2200. However, the disclosure is not limited thereto; alternatively, a socket adopter (not shown) may be installed onto the surface S2200 of the circuit board structure 2200, where the socket adopter is configured to engage with the socket 2300 and allows the socket 2300 being electrically connected to the circuit board structure 2200 overlying thereto. In such alternative embodiments, the holding element 2100 may be omitted.

In some embodiments, a semiconductor structure is installed onto the testing apparatus, in accordance with step S12 of the method 10 depicted in FIG. 1. For example, as shown in FIG. 8 and FIG. 11, the semiconductor structure 400, which is referred to as the object to-be-tested as previously mentioned, is provided and placed underneath the socket 2300 and is electrically coupled to the testing apparatus 2000 through contacting conductive pads 420 of the semiconductor structure 400 and the conductive connectors 2330 of the socket 2300 to construct the assembly of the testing apparatus 2000 and the semiconductor structure 400. It is appreciated that, some of the conductive pads 420 of the semiconductor structure 400 are assigned as signal pads (which corresponding to the conductive connectors 2332 of the conductive connectors 2330 included in the socket 2300), some of the conductive pads 420 of the semiconductor structure 400 are assigned as ground pads (which corresponding to the conductive connectors 23341 of the conductive connectors 2330 included in the socket 2300), and some of the conductive pads 420 of the semiconductor structure 400 are assigned as power pads (which corresponding to the conductive connectors 23342 of the conductive connectors 2330 included in the socket 2300), depending on the demand and design requirement/layout. With such electrical connections between the testing apparatus 2000 and the semiconductor structure 400, the semiconductor structure 400 is prepared to be tested by using the testing apparatus 2000, for example.

In the disclosure, the semiconductor structure 400 is at a water-level (e.g., before a dicing process). The semiconductor structure 400 may be in a wafer or panel form. In other words, the semiconductor structure 400 is processed in the form of a reconstructed wafer/panel. The semiconductor structure 400 may be in the form of a reconstructed wafer/panel. If considering the top view along the stacking direction, the semiconductor structure 400 is in a form of wafer-size having a diameter of about 4 inches or more. In alternative embodiments, the semiconductor structure 400 is in a form of wafer-size having a diameter of about 6 inches or more. In further alternative embodiments, the semiconductor structure 400 is in a form of wafer-size having a diameter of about 8 inches or more. In yet further alternative embodiments, the semiconductor structure 400 is in a form of wafer-size having a diameter of about 12 inches or more. For example, the semiconductor structure 400 includes a plurality of semiconductor dies or chips being interconnected, electrically and physically. The semiconductor dies or chips may be arranged along the direction X and/or the direction Y. In some embodiments, the semiconductor dies or chips are arranged in the form of a matrix, such as the N×N array or N×M array (N, M>0, N may or may not be equal to M).

It is appreciated that, in some embodiments, the semiconductor dies or chips included in the semiconductor structure 400 independently described herein may be referred to as a semiconductor chip or an integrated circuit (IC). In some embodiments, the semiconductor dies or chips included in the semiconductor structure 400 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies or chips included in the semiconductor structure 400 independently may be or include a digital chip, an analog chip or a mixed signal chip. The semiconductor dies or chips included in the semiconductor structure 400 independently may be a chip or an IC of combination-type, such as a WiFi chip simultaneously including both of a RF chip and a digital chip. In alternative embodiments, the semiconductor dies or chips included in the semiconductor structure 400 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc.; a combination thereof; or the like.

In some embodiments, the types of all of the semiconductor dies or chips included in the semiconductor structure 400 are identical. In alternative embodiments, the types of some of the semiconductor dies or chips included in the semiconductor structure 400 are different from each other, while the types of some of the semiconductor dies or chips included in the semiconductor structure 400 are identical types. In further alternative embodiments, the types of all of the semiconductor dies or chips included in the semiconductor structure 400 are different. In some embodiments, the sizes of all of the semiconductor dies or chips included in the semiconductor structure 400 are the same. In alterative embodiments, the sizes of some of the semiconductor dies or chips included in the semiconductor structure 400 are different from each other, while the sizes of some of the semiconductor dies or chips included in the semiconductor structure 400 are the same sizes. In further alternative embodiments, the sizes of all of the semiconductor dies or chips included in the semiconductor structure 400 are different. In some embodiments, the shapes of all of the semiconductor dies or chips included in the semiconductor structure 400 are identical. In alternative embodiments, the shapes of some of the s semiconductor dies or chips included in the semiconductor structure 400 are different from each other, while the shapes of some of the semiconductor dies or chips included in the semiconductor structure 400 are identical. In further alternative embodiments, the shapes of all of the semiconductor dies or chips included in the semiconductor structure 400 are different. The types, sizes and shapes of each of the semiconductor dies or chips included in the semiconductor structure 400 are independent from each other, and may be selected and designed based on the demand, the disclosure is not limited thereto. Since there are various and numerous types of the semiconductor dies or chips included in the semiconductor structure 400 could be chosen, the disclosure does not limit the type of the semiconductor dies or chips included in the semiconductor structure 400, as long as the semiconductor structure 400 is at wafer-level with the semiconductor dies or chips included therein having sufficient components to perform the designated propose; thus, the detailed structure of the semiconductor structure 400 is omitted for brevity.

In some embodiments, a test sequence (such as an automated test sequence) is performed on the semiconductor structure through the testing apparatus, in accordance with step S13 of the method 10 depicted in FIG. 1. In a testing method using the testing apparatus 2000, an assembly (including the testing apparatus 2000, the semiconductor structure 400, the controller 200 and the testing circuit structure 100) may have several possible testing electrical transmitting paths to test the semiconductor structure 400. For example, a testing electrical transmitting path is discussed below for illustrative purposes, however the disclosure is not limited herein. In a non-limiting example, an electric signal (e.g., a testing electric signal) is sent from the controller 200 to the semiconductor structure 400 by way of the testing circuit structure 100, the circuit board structure 2200, and the conductive connectors 2330 of the socket 2300; and the electric signal (e.g., the responsive electric signal, sometimes referred to as a loopback (feedback) signal) is sent from the semiconductor structure 400 to the controller 200 by way of the above components in the reversed order (e.g., the conductive connectors 2330 of the socket 2300, the circuit board structure 2200, and the testing circuit structure 100). If there is a circuit fault or electrical fault in the circuitry inside the semiconductor structure 400, then the electric signals attempting to traverse the above-described path would not be able to reach to the controller 200 or an abnormal electric signals attempting to traverse the above-described path would be received by the controller 200. After analyzing the result by the controller 200, the status of the semiconductor structure 400 will be determined.

In the above embodiments of the testing apparatus 2000, the socket 2300 and the circuit board structure 2200 are in a one-to-one configuration. However, the disclosure is not limited thereto; alternatively, for the testing apparatus 2000 in the disclosure, the socket 2300 and the circuit board structure 2200 may be in a multiple-to-one configuration, such as a 2-to-1 configuration, a 3-to-1 configuration, a 4-to-1 configuration, or so on. In some embodiments, the socket 2300 and the semiconductor structure 400 are in a one-to-one configuration.

In accordance with some embodiments, a testing apparatus for a semiconductor structure includes a socket including a flange portion, a central portion, a first conductive connector, and a second conductive connector. The central portion is surrounded by the flange portion, where the central portion includes a first opening and a second opening respectively penetrating the central portion, and a size of the first opening is less than a size of the second opening. The first conductive connector penetrates through the central portion through the first opening. The second conductive connector penetrates through the central portion through the second opening. The first conductive connector and the second conductive connector are configured to transmit electric signals for testing the semiconductor structure.

In accordance with some embodiments, a testing apparatus for a semiconductor structure includes a loadboard and a socket. The socket is disposed over and electrically coupled to the loadboard, and includes a first connector and a second connector. The first connector has two opposite first ends respectively coupled to the loadboard and the semiconductor structure. The second connector is arranged next to the first connector, and includes a power connector having two opposite second ends respectively coupled to the loadboard and the semiconductor structure, a ground connector having two opposite third ends respectively coupled to the loadboard and the semiconductor structure, and an interface structure interposing between and connected to the power connector and the ground connector, where the power connector is spatially spaced apart from the ground connector.

In accordance with some embodiments, a testing method for a semiconductor structure includes the following steps: providing a testing apparatus comprising a socket comprising a flange portion, a central portion surrounded by the flange portion and comprising a first opening and a second opening respectively penetrating the central portion, a first conductive connector penetrating through the central portion through the first opening, and a second conductive connector penetrating through the central portion through the second opening, where a size of the first opening is less than a size of the second opening, and the first conductive connector and the second conductive connector are configured to transmit electric signals for testing the semiconductor structure; installing the semiconductor structure onto the testing apparatus, where conductive pads of the semiconductor structure are electrically coupled to the first conductive connector and the second conductive connector of the socket; and performing a test sequence on the semiconductor structure through the testing apparatus.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A testing apparatus for a semiconductor structure, comprising:
a socket, comprising:
a flange portion;
a central portion, surrounded by the flange portion, wherein the central portion comprises a first opening and a second opening respectively penetrating the central portion, and a size of the first opening is less than a size of the second opening;
a first conductive connector, penetrating through the central portion through the first opening; and
a second conductive connector, penetrating through the central portion through the second opening,
wherein the first conductive connector and the second conductive connector are configured to transmit electric signals for testing the semiconductor structure.

2. The testing apparatus of claim 1, wherein the first conductive connector comprises a signal pogo pin, and the second conductive connector comprises a power pogo pin, a ground pogo pin, and an interface structure interposing between and connecting to the power pogo pin and the ground pogo pin.

3. The testing apparatus of claim 2, wherein the interface structure comprises a dielectric structure of a high-k dielectric material, wherein a dielectric constant of the high-k dielectric material is greater than 5.

4. The testing apparatus of claim 2, wherein the interface structure comprises a capacitor structure.

5. The testing apparatus of claim 4, wherein the capacitor structure comprises a plurality of capacitors arranged next to each other and each being interposed between the power pogo pin and the ground pogo pin.

6. The testing apparatus of claim 1, wherein the first conductive connector comprises a signal MEMS pin, and the second conductive connector comprises a power MEMS pin, a ground MEMS pin, and an interface structure interposing between and connecting to the power MEMS pin and the ground MEMS pin.

7. The testing apparatus of claim 6, wherein the interface structure comprises a dielectric structure of a high-k dielectric material, where a dielectric constant of the high-k dielectric material is greater than 5.

8. The testing apparatus of claim 6, wherein the interface structure comprises a capacitor structure.

9. The testing apparatus of claim 8, wherein the capacitor structure comprises a plurality of capacitors arranged next to each other and each being interposed between the power MEMS pin and the ground MEMS pin.

10. The testing apparatus of claim 1, further comprising:
a circuit board structure, over the socket, wherein the circuit board structure is electrically coupled to the socket through the first conductive connector and the second conductive,
wherein the socket is disposed between and electrically coupling the circuit board structure and the semiconductor structure.

11. The testing apparatus of claim 10, further comprising:
a cover, disposed over the socket to confine a space surrounding by the cover and the socket for accommodating the semiconductor structure.

12. A testing apparatus for a semiconductor structure, comprising:
a loadboard; and
a socket, disposed over and electrically coupled to the loadboard, comprising:
a first connector, having two opposite first ends respectively coupled to the loadboard and the semiconductor structure; and
a second connector, arranged next to the first connector, comprising:
a power connector, having two opposite second ends respectively coupled to the loadboard and the semiconductor structure;
a ground connector, having two opposite third ends respectively coupled to the loadboard and the semiconductor structure; and
an interface structure, interposing between and connected to the power connector and the ground connector, wherein the power connector is spatially spaced apart from the ground connector.

13. The testing apparatus of claim 12, wherein the first connector comprises a signal connector.

14. The testing apparatus of claim 12, wherein in a plane view along a stacking direction of the loadboard and the socket, the interface structure is extended between two opposite edges of the second connector, and a sidewall of the interface structure is flat and planar.

15. The testing apparatus of claim 12, wherein in a plane view along a stacking direction of the loadboard and the socket, the interface structure is extended between two opposite edges of the second connector, and a sidewall of the interface structure is flat and curved.

16. The testing apparatus of claim 12, wherein in a plane view along a stacking direction of the loadboard and the socket, the interface structure is extended between two opposite edges of the second connector, and a sidewall of the interface structure is f interdigitated.

17. The testing apparatus of claim 12, wherein the interface structure comprises:
a dielectric structure of a high-k dielectric material, wherein a dielectric constant of the high-k dielectric material is greater than 5; or
a plurality of capacitors arranged next to an array and each being interposed between the power connector and the ground connector.

18. A testing method for a semiconductor structure, comprising:
providing a testing apparatus comprising a socket comprising a flange portion, a central portion surrounded by the flange portion and comprising a first opening and a second opening respectively penetrating the central portion, a first conductive connector penetrating through the central portion through the first opening, and a second conductive connector penetrating through the central portion through the second opening, wherein a size of the first opening is less than a size of the second opening, and the first conductive connector and the second conductive connector are configured to transmit electric signals for testing the semiconductor structure;
installing the semiconductor structure onto the testing apparatus, wherein conductive pads of the semiconductor structure are electrically coupled to the first conductive connector and the second conductive connector of the socket; and
performing a test sequence on the semiconductor structure through the testing apparatus.

19. The testing method of claim 18, wherein performing the test sequence on the semiconductor structure through the testing apparatus comprising:
sending a testing signal from the testing apparatus to the semiconductor structure through an electrical connection path comprising the first conductive connector and the second conductive connector; and
receiving, by the testing apparatus, a responsive signal from the semiconductor structure through the electrical connection path,
wherein the responsive signal is further analyzed by a controller electrically coupled to the testing apparatus.

20. The testing method of claim 18, wherein installing the semiconductor structure onto the testing apparatus comprises:
placing the semiconductor structure into a space inside the socket, so to contact the first conductive connector and the second conductive connector of the socket to the conductive pads of the semiconductor structure; or
placing the semiconductor structure underneath and outside the socket, so to contact the first conductive connector and the second conductive connector of the socket to the conductive pads of the semiconductor structure.
